(19) United States
(12) Patent Application Publication
(10) Pub. No.: US 2020/0105723 A1
(43) Pub. Date: Apr. 2, 2020

(54) MODULE

(71) Applicant: TAIYO YUDEN CO., LTD., Tokyo (JP)

(72) Inventors: Yasuhito HAGIWARA, Takasaki-shi (JP); Shigeru YOKOYAMA, Takasaki-shi (JP); Michiharu KAWANO, Takasaki-shi (JP); Takaki HAMAMOTO, Takasaki-shi (JP)

(21) Appl. No.: 16/584,902

(22) Filed: Sep. 26, 2019

(30) Foreign Application Priority Data
Sep. 28, 2018 (JP) 2018-183813
Sep. 28, 2018 (JP) 2018-183814
Aug. 19, 2019 (JP) 2019-149664

(51) Int. Cl. H01L 25/07; H01L 23/14; H01L 23/00; H01L 23/495; H01L 23/538; H01L 25/00; H01L 21/48; H01L 23/31

(52) U.S. Cl. CPC H01L 25/072; H01L 2224/32245; H01L 24/32; H01L 23/49575; H01L 23/49513; H01L 23/49562; H01L 23/5387; H01L 25/50; H01L 21/481; H01L 24/83; H01L 21/4839; H01L 24/33; H01L 23/3135; H01L 2224/32225; H01L 2224/33181; H01L 23/145

(57) ABSTRACT

A module includes: a resin insulating layer; a first electronic component mounted on a lower surface of the resin insulating layer and including first and second terminals on an upper surface of the first electronic component; a resin bonding layer bonding the lower surface of the resin insulating layer to the upper surface of the first electronic component; first and second wiring lines located on inner surfaces of at least one first through hole and at least one second through hole penetrating through the resin insulating layer and the resin bonding layer, respectively, located on an upper surface of the resin insulating layer, and connecting to the first and second terminals, respectively, wherein an opening penetrating through the resin insulating layer and the resin bonding layer is provided between the first and second terminals and between the first and second wiring lines, and no other metal layers are provided.

### CROSS-REFERENCE TO RELATED APPLICATION

This application is based upon and claims the benefits of priorities of the prior Japanese Patent Application No. 2018-183813, filed on Sep. 28, 2018, the prior Japanese Patent Application No. 2018-183814, filed on Sep. 28, 2018, and the prior Japanese Patent Application No. 2019-149664, filed on Aug. 19, 2019, the entire contents of which are incorporated herein by reference.

### FIELD

A certain aspect of the present disclosure relates to a module.

### BACKGROUND

Using metal thin wires such as bonding wires has been known as one of methods of electrically connecting electronic components such as power semiconductor elements mounted on a lead frame to a lead of the lead frame. It is known that in a power module including a power semiconductor element mounted therein, an electronic component is mounted on the upper surface of an insulating layer, and a wiring line coupled to the electronic component from the lower surface of the insulating layer through a through hole penetrating through the insulating layer is provided as disclosed in, for example, Japanese Patent Application Publication No. 2016-46523.

### SUMMARY

According to a first aspect of the present invention, there is provided a module including: a resin insulating layer; a first electronic component mounted on a lower surface of the resin insulating layer, the first electronic component including a first terminal and a second terminal on an upper surface of the first electronic component; a resin bonding layer bonding the lower surface of the resin insulating layer to the upper surface of the first electronic component; a first wiring line located on an inner surface of at least one first through hole and an upper surface of the resin insulating layer, the first wiring line connecting to the first terminal, the at least one first through hole penetrating through the resin insulating layer and the resin bonding layer; and a second wiring line located on an inner surface of at least one second through hole and an upper surface of the resin insulating layer, the second wiring line connecting to the second terminal, the at least one second through hole penetrating through the resin insulating layer and the resin bonding layer, wherein an opening penetrating through the resin insulating layer and the resin bonding layer is provided between the first terminal and the second terminal and between the first wiring line and the second wiring line, and no other metal layers are provided.

According to a second aspect of the present invention, there is provided a module including: a sheet module including an insulating layer, an electronic component, a first wiring line, and a second wiring line, the electronic component being mounted on a lower surface of the insulating layer, the first wiring line being electrically connected to the electronic component through a first through hole, extending on an upper surface of the insulating layer, and including a first pad in an end of the first wiring line, the first through hole penetrating through the insulating layer, the second wiring line being electrically connected to the electronic component through a second through hole, extending on the upper surface of the insulating layer, and including a second pad in an end of the second wiring line, the second through hole penetrating through the insulating layer; a die pad to which a lower surface of the electronic component is bonded, a first lead including a first frame pad to which the first pad is bonded, the first lead extending from the first frame pad; a second lead including a second frame pad to which the second pad is bonded, the second lead extending from the second frame pad in a direction substantially parallel to an extension direction of the first lead; and a third lead located between the first lead and the second lead and integrally formed with the die pad, the third lead extending in a direction substantially parallel to the extension direction of the first lead and an extension direction of the second lead.

According to a third aspect of the present invention, there is provided a module including: an insulating layer having a flexibility; an electronic component mounted on a lower surface of the insulating layer; a wiring line electrically connected to the electronic component through a through hole penetrating through the insulating layer, the wiring line extending on an upper surface of the insulating layer, and including a pad in an end of the wiring line; and a metal layer located on the insulating layer so as to surround an opening provided to the insulating layer adjacent to the pad.

### BRIEF DESCRIPTION OF THE DRAWINGS

FIG. 1A through FIG. 1D are cross-sectional views illustrating a method of manufacturing a module in accordance with a first embodiment;

FIG. 2A and FIG. 2B are plan views illustrating the method of manufacturing the module in accordance with the first embodiment;

FIG. 3A and FIG. 3B are plan views illustrating the method of manufacturing the module in accordance with the first embodiment;

FIG. 4A is a plan view of a lead frame in the first embodiment, FIG. 4B is a cross-sectional view taken along line A-A in FIG. 4A, and FIG. 4C is a cross-sectional view taken along line B-B in FIG. 4A;

FIG. 5 is a plan view illustrating the method of manufacturing the module in accordance with the first embodiment;

FIG. 6 is a plan view illustrating the method of manufacturing the module in accordance with the first embodiment;

FIG. 7A is a cross-sectional view taken along line A-A in FIG. 6, and FIG. 7B is a cross-sectional view taken along line B-B in FIG. 6;

FIG. 8A and FIG. 8B are cross-sectional views illustrating the method of manufacturing the module in accordance with the first embodiment;

FIG. 9 is a plan view illustrating the method of manufacturing the module in accordance with the first embodiment;

FIG. 10 is a plan view illustrating the method of manufacturing the module in accordance with the first embodiment;

FIG. 11A through FIG. 11C are cross-sectional views illustrating the method of manufacturing the module in accordance with the first embodiment;

FIG. 12 is a plan view of the module in accordance with the first embodiment;

FIG. 13A is a cross-sectional view taken along line A-A in FIG. 12, and FIG. 13B is a cross-sectional view taken along line B-B in FIG. 12;

FIG. 14A is a plan view of a module in accordance with a first variation of the first embodiment, and FIG. 14B is a cross-sectional view taken along line A-A in FIG. 14A;

FIG. 15A is a cross-sectional view of a module in accordance with a second variation of the first embodiment, and FIG. 15B and FIG. 15C are cross-sectional views of a module in accordance with a third variation of the first embodiment;

FIG. 16A is a plan view of a module in accordance with a fourth variation of the first embodiment, and FIG. 16B is a cross-sectional view taken along line A-A in FIG. 16A;

FIG. 17A is a plan view of a sheet module in a fifth variation of the first embodiment, and FIG. 17B is a plan view illustrating a method of manufacturing the module in the fifth variation of the first embodiment;

FIG. 18A is a plan view of a sheet module in a sixth variation of the first embodiment, and FIG. 18B is a plan view illustrating a method of manufacturing the module in the sixth variation of the first embodiment;

FIG. 19A is a plan view of a sheet module in accordance with a seventh variation of the first embodiment, and FIG. 19B is a plan view illustrating a method of manufacturing the module in accordance with the seventh variation of the first embodiment;

FIG. 20A is a plan view of a sheet module in an eighth variation of the first embodiment, and FIG. 20B is a plan view illustrating a method of manufacturing the module in the eighth variation of the first embodiment;

FIG. 21A is a plan view of a module in accordance with a second embodiment, and FIG. 21B is an enlarged view of a part around the electronic component in FIG. 21A;

FIG. 22 is a cross-sectional view taken along line A-A in FIG. 21A;

FIG. 23A through FIG. 23D are cross-sectional views (No. 1) illustrating a method of manufacturing the module in accordance with the second embodiment;

FIG. 24A and FIG. 24B are cross-sectional views (No. 2) illustrating a method of manufacturing the module in accordance with the second embodiment;

FIG. 25A and FIG. 25B are cross-sectional views of a module in accordance with a first comparative example;

FIG. 26A and FIG. 26B are plan views of modules in accordance with first and second variations of the second embodiment, respectively;

FIG. 27 is a cross-sectional view of a module in accordance with a third variation of the second embodiment;

FIG. 28 is a cross-sectional view of a module in accordance with a fourth variation of the second embodiment;

FIG. 29 is a plan view of a sheet module in accordance with a fifth variation of the second embodiment;

FIG. 30A is a plan view of a lead frame in a sixth variation of the second embodiment, FIG. 30B is a cross-sectional view taken along line A-A in FIG. 30A, and FIG. 30C is a cross-sectional view taken along line B-B in FIG. 30A;

FIG. 31 is a plan view of a module in accordance with the sixth variation of the second embodiment;

FIG. 32A is a plan view of a sheet module in a seventh variation of the second embodiment, and FIG. 32B is a cross-sectional view taken along line A-A in FIG. 32A;

FIG. 33A is a plan view of a lead frame in a seventh variation of the second embodiment, and FIG. 33B is a cross-sectional view taken along line A-A in FIG. 33A; and

FIG. 34A is a plan view of the module in accordance with the seventh variation of the second embodiment, and FIG. 34B is a cross-sectional view taken along line A-A in FIG. 34A.

### DETAILED DESCRIPTION

When an electronic component and a lead are interconnected with use of a bonding wire, the bonding wire is formed in a loop shape. Thus, the module thickens. When the electronic component generates heat, a resin insulating layer strains because of the difference in linear thermal expansion coefficient between the resin insulating layer and a wiring line. This may cause the wiring line in the through hole to peel from the electronic component.

Hereinafter, a description will be given of embodiments with reference to the accompanying drawings.

### First Embodiment

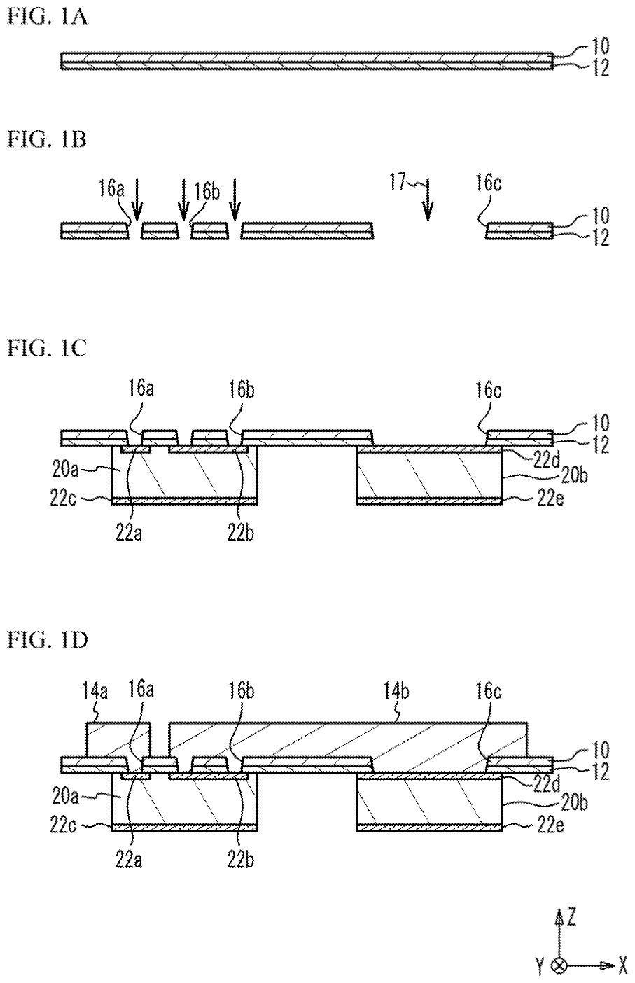

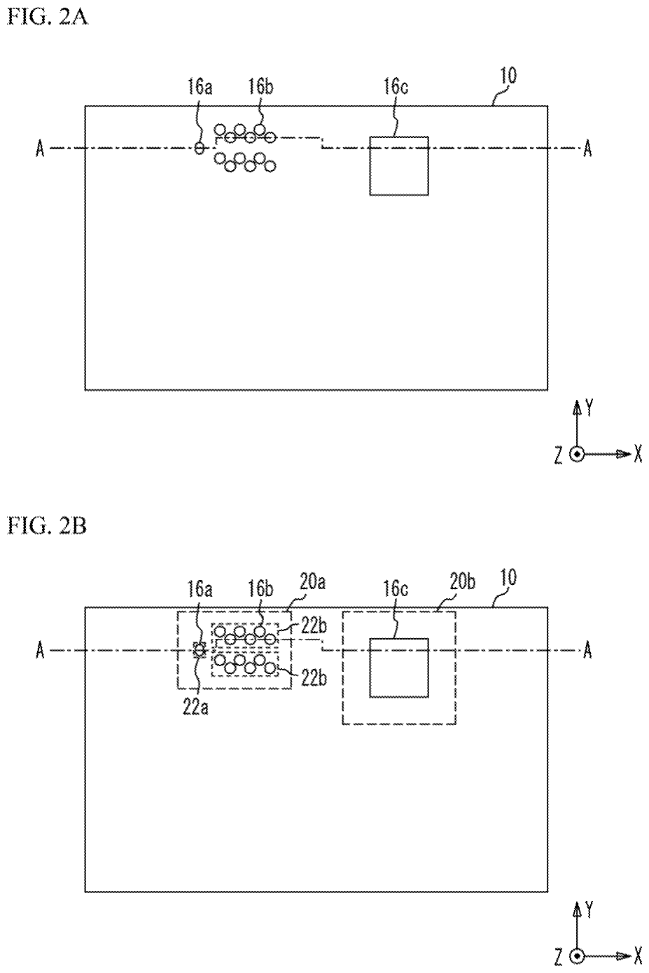

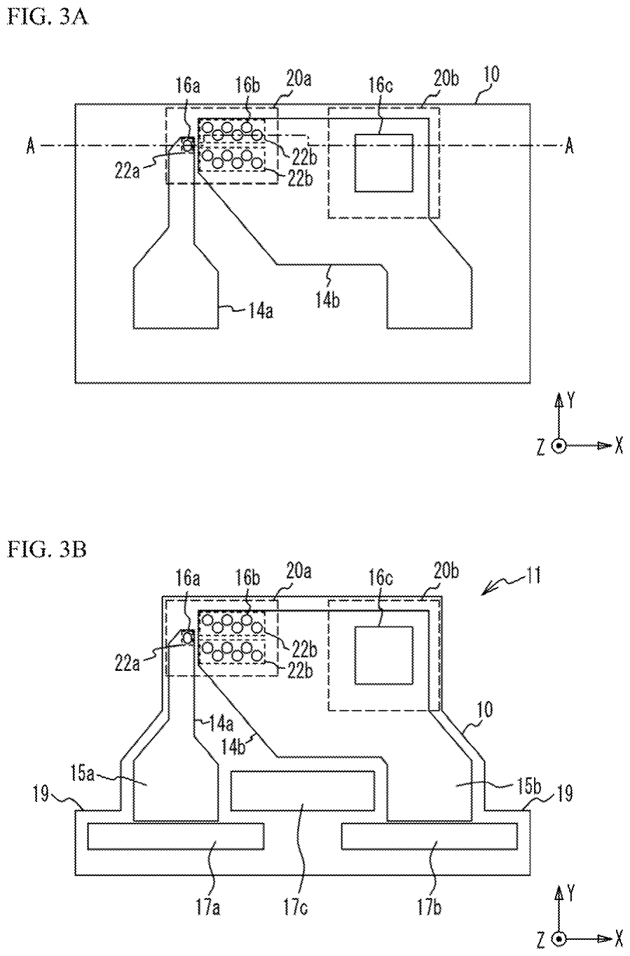

FIG. 1A through FIG. 1D are cross-sectional views illustrating a method of manufacturing a module in accordance with a first embodiment, and FIG. 2A through FIG. 3B are plan views illustrating the method of manufacturing the module in accordance with the first embodiment. FIG. 1B through FIG. 1D respectively correspond to the cross-sectional views taken along line A-A in FIG. 2A through FIG. 3A. In planar directions of an insulating layer 10, a direction in which electronic components 20a and 20b are arranged is defined as an X direction, a direction perpendicular to the X direction is defined as a Y direction, and the thickness direction of the insulating layer 10 is defined as a Z direction. FIG. 2A through FIG. 3B illustrate the insulating layer 10, through holes 16a through 16c, the electronic components 20a and 20b, and wiring lines 14a and 14b. In FIG. 1B through FIG. 1D, because of space limitations, two through holes 16b are illustrated.

As illustrated in FIG. 1A, a bonding layer 12 is applied onto the lower surface of the insulating layer 10. The bonding layer 12 is applied by, for example, spin coating, spray coating, or ink jetting. The insulating layer 10 is a resin insulating layer made of polyimide or the like. The bonding layer 12 is formed of a resin adhesive agent made of, for example, an epoxy resin. The insulating layer 10 has a thickness of, for example, 20 μm to 50 μm. The thickness of the bonding layer 12 is, for example, 5 μm to 20 μm, and is less than the thickness of the insulating layer 10.

As illustrated in FIG. 1B and FIG. 2A, the through holes 16a through 16c penetrating through the insulating layer 10 and the bonding layer 12 are formed. The through holes 16a through 16c are formed by irradiating the insulating layer 10 and the bonding layer 12 with a laser beam 17 of, for example, an ultraviolet light, a visible light, or an infrared light. The through holes 16a through 16c have dimensions of, for example, 30 μm to 500 μm. Although one large through hole 16c is formed in FIG. 1B, as with the through holes 16b, a plurality of the through holes 16c may be formed.

As illustrated in FIG. 1C and FIG. 2B, the electronic components 20a and 20b are made to be in contact with the lower surface of the bonding layer 12. The bonding layer 12 is hardened by heat treatment to bond the electronic components 20a and 20b and the insulating layer 10. The heat treatment is conducted at a temperature of, for example, 200° C. to 300° C. To enhance the tackiness of the bonding layer 12, heat treatment may be conducted before the electronic components 20a and 20b are placed on the bonding layer 12.

The electronic components 20a and 20b are power elements, and are transistors such as, but not limited to, insulated gate bipolar transistors (IGBTs), bipolar transistors, or field effect transistors (FETs), or diodes. A semiconductor such as Si, GaN, or SiC is used in the transistor or the diode. The electronic components 20a and 20b are, for example, bare chips. In this example, the electronic component 20a is a bare chip of a vertical SiC transistor. The electronic component 20b is a bare chip of a diode.

Terminals 22a and 22b are located on the upper surface of the electronic component 20a, and a terminal 22c is located on the lower surface of the electronic component 20a. The terminal 22a is a gate terminal, the terminal 22b is a source terminal, and the terminal 22c is a drain terminal. A terminal 22d is located on the upper surface of the electronic component 20b, and a terminal 22e is located on the lower surface of the electronic component 20b. The terminal 22d is an anode terminal, and the terminal 22e is a cathode terminal. The terminals 22a through 22e are formed in the site of the production maker of the electronic components 20a and 20b, and are metal layers made of, for example, copper, gold, or aluminum.

The terminals 22a, 22b, and 22d of the electronic components 20a and 20b are respectively exposed to the through holes 16a, 16b, and 16c. One through hole 16a is provided, and six through holes 16b are provided for each of the two terminals 22b. A large current flows between the source terminal and the drain terminal. Since the gate terminal is a control terminal, a large current does not flow through the gate terminal. Thus, the terminal 22a is smaller than the terminal 22b. The total area of the through hole 16a is less than the total area of the through holes 16b. The source terminal is referred to as a current inflow terminal or a current outflow terminal, and the drain terminal is referred to as a current outflow terminal or a current inflow terminal. The current inflow terminal and the current outflow terminal may be an emitter terminal, or may be a collector terminal. The control terminal may be a base terminal.

As illustrated in FIG. 1D and FIG. 3A, the wiring lines 14a and 14b are formed on the upper surface of the insulating layer 10 and the inner surfaces of the through holes 16a through 16c. A method of forming the wiring lines 14a and 14b will be described. A seed layer is formed on the upper surface of the insulating layer 10 and the inner surfaces of the through holes 16a and 16b. The seed layer is formed by, for example, sputtering. The seed layer is a metal layer including a titanium layer and a copper layer stacked in this order from the insulating layer 10 side, for example. A plated layer is formed on the upper surface of the seed layer. The plated layer is a metal layer such as, but not limited to, a copper layer. The plated layer is formed by, for example, electrolytic plating supplying a current to the seed layer. The seed layer and the plated layer form the wiring lines 14a and 14b. The wiring lines 14a and 14b may be formed by forming a plated layer across the entire surface of the insulating layer 10 by plating and then patterning the plated layer, or may be formed by forming resist having openings in regions to be covered with a plate, and then forming a plated film in the regions.

The wiring line 14a is electrically connected to the terminal 22a through the through hole 16a. The wiring line 14b is electrically connected to the terminals 22b through the through holes 16b, and is electrically connected to the terminal 22d through the through hole 16c. The wiring lines 14a and 14b are formed of a metal layer such as, but not limited to, a copper layer. The thicknesses of the wiring lines 14a and 14b are, for example, 50 μm to 100 μm, and are greater than the thickness of the insulating layer 10. The wiring lines 14a and 14b may be thinner than the insulating layer 10.

The wiring line 14a is thinner than the wiring line 14b, and extends from the electronic component 20a in the negative Y direction. A pad 15a with a wide width, which is integrally formed with the wiring line 14a, is located in the end (the negative Y direction end (the forward end in FIG. 1D)) of the wiring line 14a. The wiring line 14b connects the electronic components 20a and 20b, and extends from the electronic components 20a and 20b in the negative Y direction (the forward direction in FIG. 1D). The end of the wiring line 14b is a pad 15b. The wiring line 14b is narrow between the pad 15b and the part where the wiring line 14b is connected to the electronic components 20a and 20b. The pad 15b has a width greater than the smallest width of the wiring line 14b, and is located in the end of the wiring line 14b.

As illustrated in FIG. 3B, the insulating layer 10 is cut into a desired shape, and openings 17a through 17c are then formed. A laser beam or a die cutting device is used for cutting. The openings 17a and 17b of the insulating layer 10 are formed in the negative Y direction relative to the pads 15a and 15b. The openings 17a and 17b have slit shapes extending in the X direction. The opening 17c is formed between the pads 15a and 15b. The opening 17c has a slit shape extending in the X direction. The positive Y direction edge, the negative X direction edge (the edge located in the negative X direction relative to the electronic component 20a (the edge located at the left side of the electronic component 20a)), and the positive X direction edge (the edge located in the positive X direction relative to the electronic component 20b (the edge located at the right side of the electronic component 20b)) of the insulating layer 10 are cut along the outer peripheries of the electronic components 20a and 20b and the wiring lines 14a and 14b such that the insulating layer 10 is slightly larger than the area defined by the outer peripheries. This forms the outer periphery of the insulating layer 10. A connection portion 19 extending in the X direction is formed in the negative Y direction end of the insulating layer 10. Through the above-described method, completed is a sheet module 11 in which the electronic components 20a and 20b are mounted on the negative Z direction surface of the insulating layer 10, the wiring lines 14a and 14b are formed on the positive Z direction surface of the insulating layer 10, and the openings 17a through 17c are formed in the insulating layer 10.

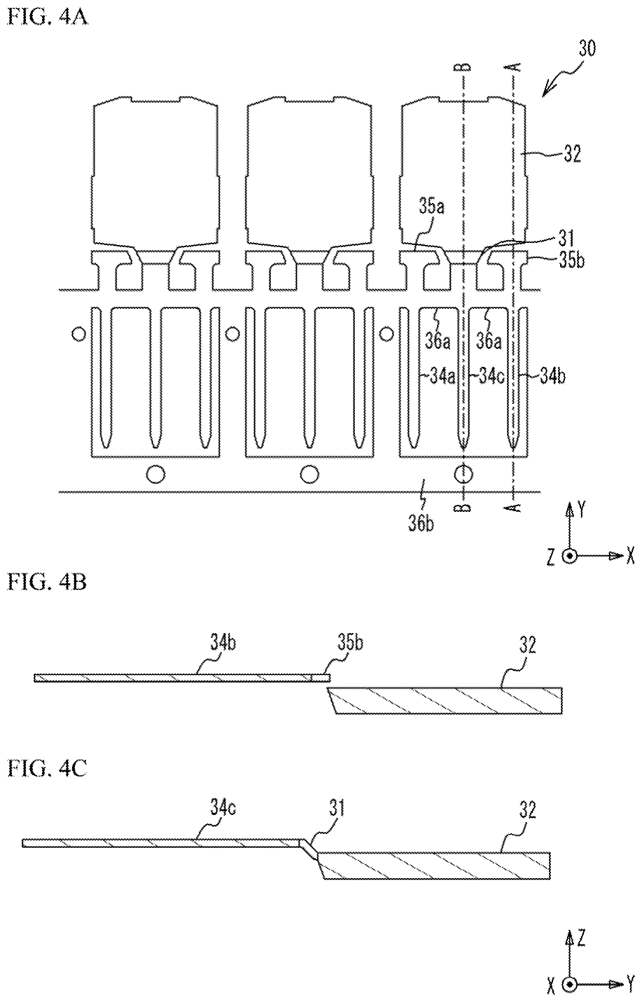

FIG. 4A is a plan view of a lead frame in the first embodiment, FIG. 4B is a cross-sectional view taken along line A-A in FIG. 4A, and FIG. 4C is a cross-sectional view taken along line B-B in FIG. 4A. In a lead frame 30, a die pad (also referred to as an island) 32 is used as a mounting area for the electronic components 20a and 20b, and has a plate-like shape having a thickness. The die pad 32 and a lead 34c are integrally formed through a connection portion 31, and the lead 34c extends in the negative Y direction. First ends of leads 34a and 34b are adjacent to the die pad 32. The leads 34a and 34b extend from the first ends, which are adjacent to the die pad 32, in the negative Y direction. The positive Y direction ends of the leads 34a and 34b, i.e., the ends adjacent to the die pad 32, are frame pads 35a and 35b processed flat in a plate-like shape.

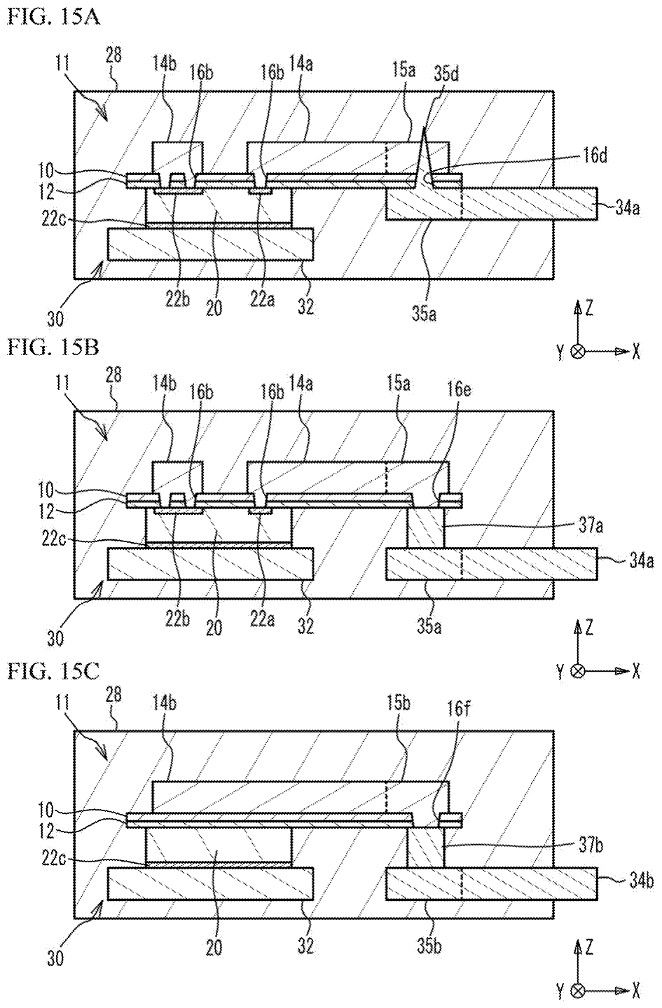

The frame pads 35a and 35b are flat because the flat pads 15a and 15b on the insulating layer 10 are attached to the frame pads 35a and 35b. The leads 34a through 34c are connected by a tie bar 36a, and a plurality of the lead frames 30 is arranged in the X direction. The leads 34a through 34c and the frame pads 35a and 35b are pushed up by a press, and are located in the positive Z direction relative to the upper surface of the die pad 32. As in FIG. 15C described later, the leads 34a through 34c and the frame pads 35a and 35b may be in the same plane with the upper surface of the die pad 32. The lead frame 30 is made of a metal such as, but not limited to, a copper alloy.

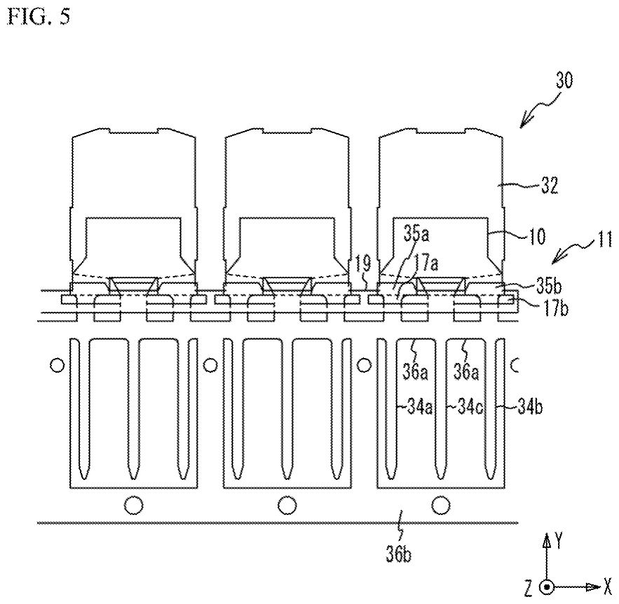

FIG. 5 is a plan view illustrating the method of manufacturing the module in accordance with the first embodiment. FIG. 5 illustrates the lead frame 30 and the insulating layer 10. As illustrated in FIG. 5, the insulating layers 10 connected in the X direction by the connection portions 19 are placed over the lead frames 30. The frame pads 35a and 35b are respectively inserted into the openings 17a and 17b.

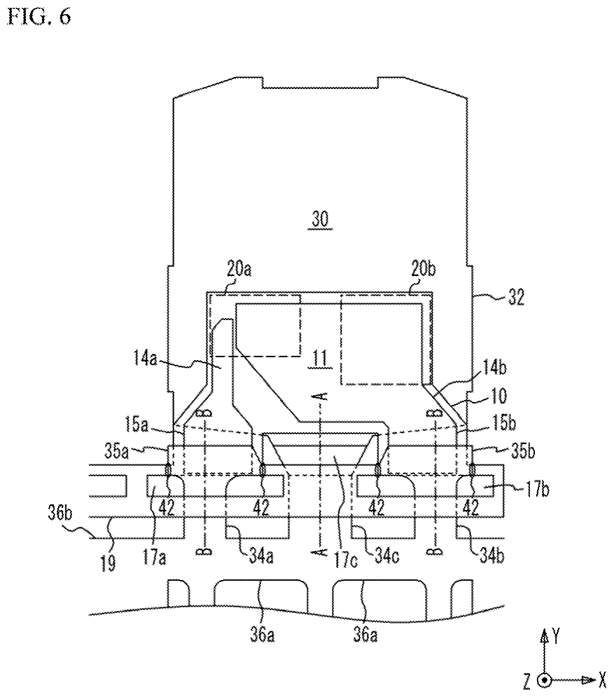

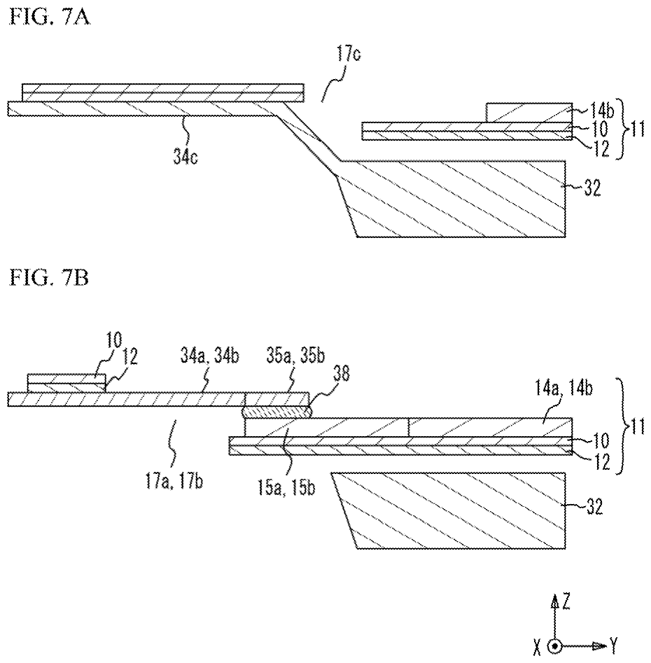

FIG. 6 is a plan view illustrating the method of manufacturing the module in accordance with the first embodiment, FIG. 7A is a cross-sectional view taken along line A-A in FIG. 6, and FIG. 7B is a cross-sectional view taken along line B-B in FIG. 6. FIG. 6 illustrates the lead frame 30, the insulating layer 10, the wiring lines 14a and 14b, and the electronic components 20a and 20b.

As illustrated in FIG. 6 through FIG. 7B, the frame pads 35a and 35b are inserted into the openings 17a and 17b from the negative Y direction. Specifically, the frame pads 35a and 35b of the leads 34a and 34b pass through the openings 17a and 17b from the negative Z direction side of the insulating layer 10, and are inserted toward the positive Z direction side of the insulating layer 10. Thus, the negative Z direction surfaces of the frame pads 35a and 35b of the leads 34a and 34b faces the positive Z direction surfaces of the pads 15a and 15b of the insulating layer 10.

In this state, the sheet module 11 including, as a base, the insulating layer 10 illustrated in FIG. 3B is fixed to the lead frame 30. The openings 17a and 17b are supporting means fixing the lead frame 30 and the sheet module 11 to each other. Alternatively, the frame pads 35a and 35b of the lead frame 30 are supporting means fixing the insulating layer 10 and the lead frame 30 to each other. Accordingly, the ends of the pads 15a and 15b are located under the frame pads 35a and 35b. Since the lead 34c is coupled to the die pad 32, the lead 34c is not inserted in the opening 17c.

The pads 15a and 15b and the frame pads 35a and 35b are respectively bonded to each other by a bonding layer 38. The bonding layer 38 is formed of a metal paste such as, but not limited to, a copper paste or a silver paste, or solder. The bonding layer 38 is provided in advance on the upper surfaces of the pads 15a and 15b, or is provided in advance on the lower surfaces of the frame pads 35a and 35b. When the bonding layer 38 is formed of a metal paste, the bonding layer 38 is applied by, for example, printing, potting, spray coating, or ink jetting. The bonding layer 38 is made to be in contact with the pads 15a and 15b and the frame pads 35a and 35b. The bonding layer 38 is baked by heat treatment. This causes the pads 15a and 15b and the frame pads 35a and 35b to be thermally, mechanically, electrically connected, respectively. The heat treatment temperature is, for example, 200° C. to 300° C., and is a temperature at which the insulating layer 10 and the bonding layer 12 are not softened.

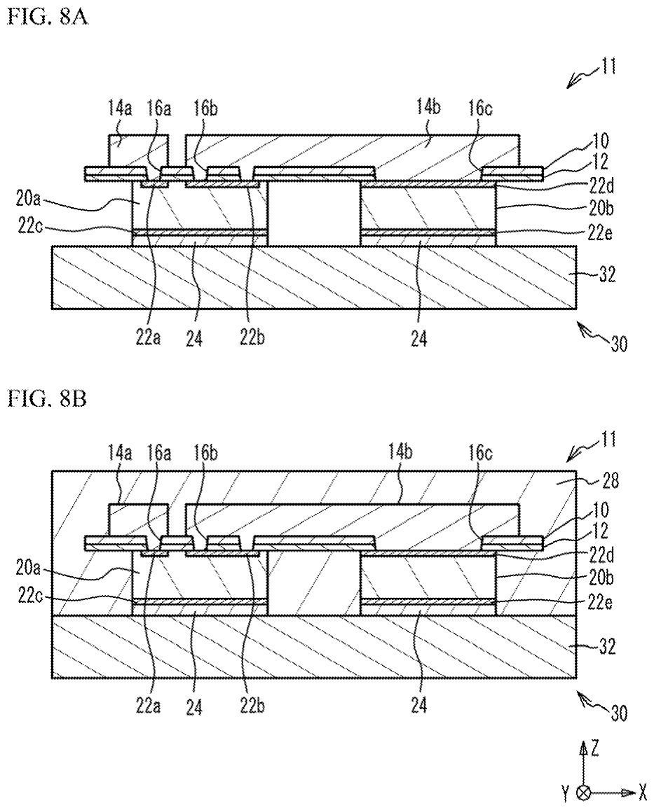

FIG. 8A and FIG. 8B are cross-sectional views illustrating the method of manufacturing the module in accordance with the first embodiment. As illustrated in FIG. 8A, the lower surfaces of the electronic components 20a and 20b are mounted on the upper surface of the die pad 32, and then bonded to the die pad 32 with use of a bonding layer 24. The bonding layer 24 is formed of a metal paste such as, but not limited to, a copper paste or a silver paste, or solder. The bonding layer 24 is provided in advance on the upper surface of the die pad 32. When the bonding layer 24 is formed of a metal paste, the bonding layer 24 is applied by, for example, printing, potting, spray coating, or ink jetting. The bonding layer 24 is baked by heat treatment. This causes the terminals 22c and 22e and the die pad 32 to be thermally, mechanically, electrically connected. The heat treatment temperature is, for example, 200° C. to 300° C., and is a temperature at which the insulating layer 10 and the bonding layer 12 are not softened.

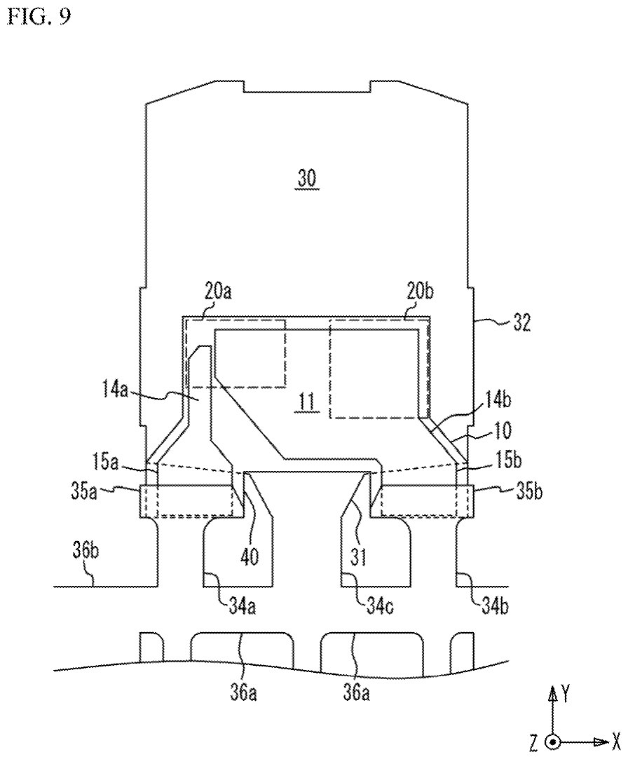

FIG. 9 is a plan view illustrating the method of manufacturing the module in accordance with the first embodiment. FIG. 9 illustrates the lead frame 30, the insulating layer 10, the wiring lines 14a and 14b, and the electronic components 20a and 20b.

As illustrated in FIG. 9, four regions 42 (see FIG. 6) of the insulating layer 10 are cut. The four regions 42 are cut with use of, for example, a laser beam, a die cutting device, or a cutter. This removes the insulating layer 10 and the bonding layer 12 at both sides in the X direction of the negative Y direction ends of the pads 15a and 15b, and a forked leg structure of the insulating layer 10 and the bonding layer 12 illustrated in FIG. 9 is formed. In other words, the connection portion 19 in FIG. 3B is removed, and a structure in which a recessed cutout 40 is formed between the pads 15a and 15b is obtained.

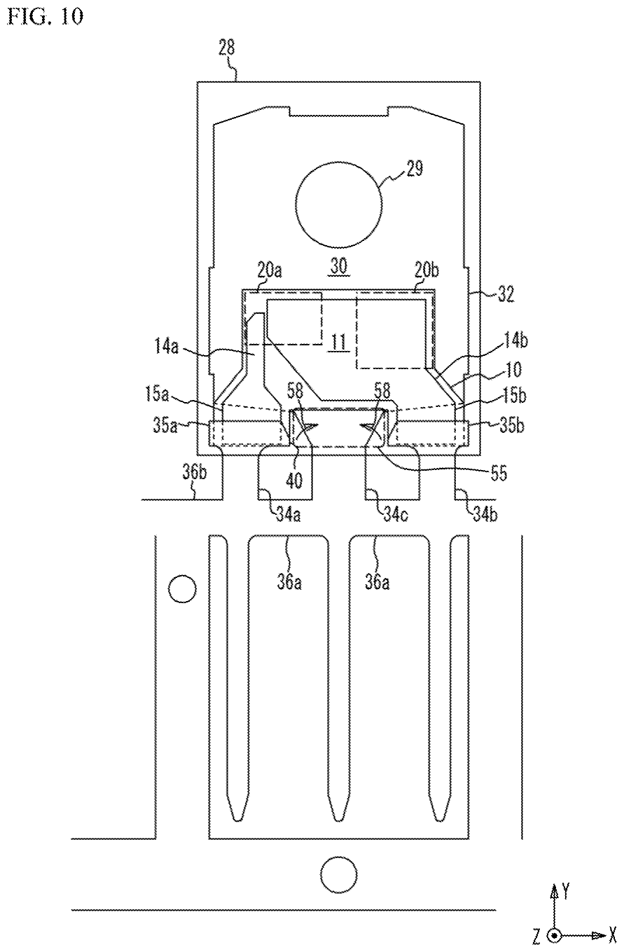

FIG. 10 is a plan view illustrating the method of manufacturing the module in accordance with the first embodiment. FIG. 10 illustrates the lead frame 30, the insulating layer 10, the wiring lines 14a and 14b, the electronic component 20a and 20b, and a sealing resin 28.

As illustrated in FIG. 10 and FIG. 8B, the electronic components 20a and 20b are mounted on the die pad 32. The sealing resin 28 is formed so as to cover the sheet module 11 formed of the insulating layer 10 on which the electronic components 20a and 20b are mounted through the bonding layer 12 and the wiring lines 14a and 14b are formed. The sealing resin 28 is a thermosetting resin such as, but not limited to, epoxy resin. The sealing resin 28 is formed by transfer molding, vacuum printing, or compression molding.

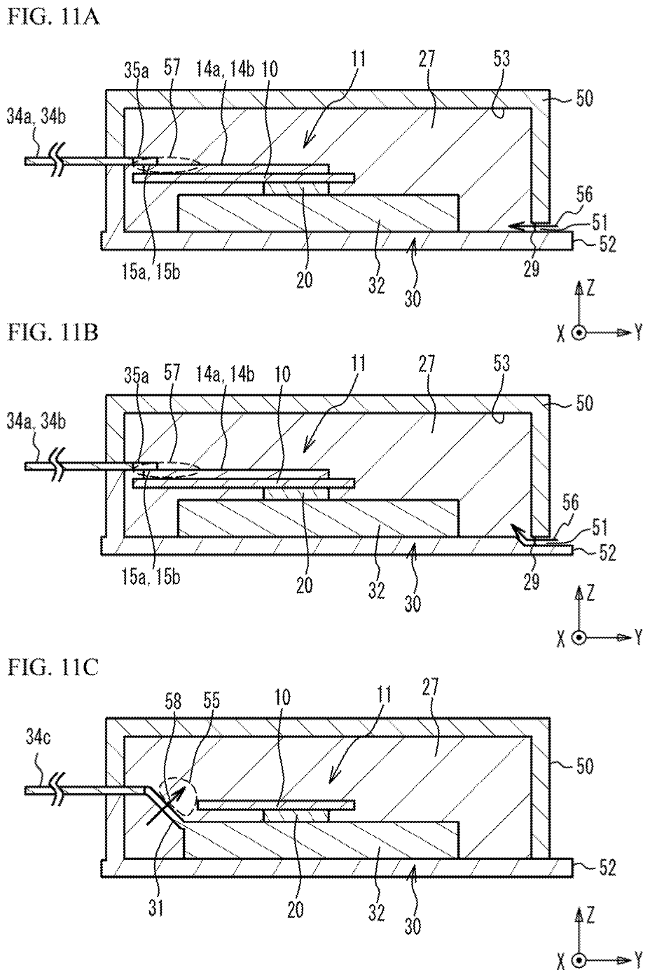

FIG. 11A through FIG. 11C are cross-sectional views illustrating the method of manufacturing the module in accordance with the first embodiment. FIG. 11A and FIG. 11B are cross-sectional views around the leads 34a and 34c, and FIG. 11C is a cross-sectional view of a part around the lead 34c, and the illustration of the bonding layer 12, 24, and 38 is omitted. As illustrated in FIG. 11A and FIG. 11B, for example, in the case of transfer molding, the lead frame 30 on which the sheet module 11 is mounted is placed on a lower mold 52. The lower surface of the die pad 32 is made to be in contact with the lower mold 52, and an upper mold 50 and the lower mold 52 are made to be in contact with each other. An injection gate 51 is provided in a part between the upper mold 50 and the lower mold 52. Thereafter, as indicated by an arrow 56, a resin 27 is injected through the gate 51 into a cavity 53 formed between the upper mold 50 and the lower mold 52. Thereafter, the resin 27 is cured by heating. When the lower surface of the die pad 32 is made to be in contact with the lower mold 52, the lower surface of the die pad 32 is exposed from the sealing resin 28. When the lower mold 52 is made to be located away from the lower surface of the die pad 32, the lower surface of the die pad 32 is sealed by the sealing resin 28. Any of the methods may be used as desired. Thereafter, the lead frame 30 is unmolded from the upper mold 50 and the lower mold 52. Thereafter, the tie bars 36a and 36b are cut to obtain the individual sheet modules 11.

In the case of transfer molding, the injection pressure of the melted resin 27 is high. Thus, when the flow of the resin 27 in the negative Z direction is generated in a region 57, a force in the negative Z direction is applied to the sheet module 11. Thus, a force that peels the bonding is generated between the frame pads 35a and 35b and the pads 15a and 15b. Thus, the flow of the resin 27 is made to be in the direction parallel to the upper surface of the die pad 32 (the XY plane direction) and/or in the direction from the lower surface of the die pad 32 to the upper surface of the die pad 32 (the positive Z direction). This configuration reduces the force that peels the bonding between the frame pads 35a and 35b and the pads 15a and 15b.

Since the melted resin 27 has a high viscosity, the melted resin 27 spreads in the cavity 53 while maintaining its flow direction in the direction in which the melted resin 27 was injected. In FIG. 11A, the gate 51 is located on the lateral side of the upper mold 50. The resin 27 is injected through the gate 51 in the negative Y direction as indicated by the arrow 56. Accordingly, the resin 27 spreads in the cavity 53 in the negative Y direction, and the flow of the resin in the region 57 is in the XY plane direction. Thus, the force in the negative Z direction in the region 57 becomes weak. A resin seal gate trace 29 is formed on the side surface of the sealing resin 28.

In FIG. 11B, the gate 51 is provided to the upper surface of the lower mold 52. The resin 27 is injected through the gate 51 in the negative Y direction and the positive Z direction as indicated by the arrow 56. Accordingly, the resin 27 spreads in the cavity 53 in the negative Y direction and the positive Z direction, and the flow of the resin in the region 57 is in the positive Z direction. Thus, the force in the negative Z direction in the region 57 becomes weak. The resin seal gate trace 29 is formed on the lower surface of the sealing resin 28. As described above, the gate 51 is preferably provided in the position corresponding to any one of the lower surface and four side surfaces of the sealing resin 28.

The recessed cutout 40 will be described. In FIG. 10 and FIG. 11C, a space 55 exists among the frame pads 35a and 35b, the connection portion 31, and the die pad 32. The space 55 becomes a flow path for the resin 27. When the insulating layer 10 has no cutout 40, the resin 27 flowing into the space 55 from the spaces in the positive X direction and the negative X direction relative to the connection portion 31 as indicated by arrows 58 applies a pressure to the insulating layer 10. This results in a load on the sheet module 11. When the cutout 40 is formed in the insulating layer 10, the space 55 that is the inflow path for the resin 27 is opened. To prevent the pressure of the resin 27 from being applied to the insulating layer 10, it is preferable that the positive Y direction edge of the cutout 40 overlaps with the die pad 32, and the positive and negative X direction edges of the cutout 40 are adjacent to or overlap with the frame pads 35a and 35b as viewed from the Z direction. This configuration expands the inflow path for the resin 27, and reduces the load on the sheet module 11. To secure the flow path for the resin 27 indicated by the arrows 58, it is sufficient if the cutout 40 is located in at least one of a part between the lead 34c and the frame pad 35a and a part between the lead 34c and the frame pad 35b.

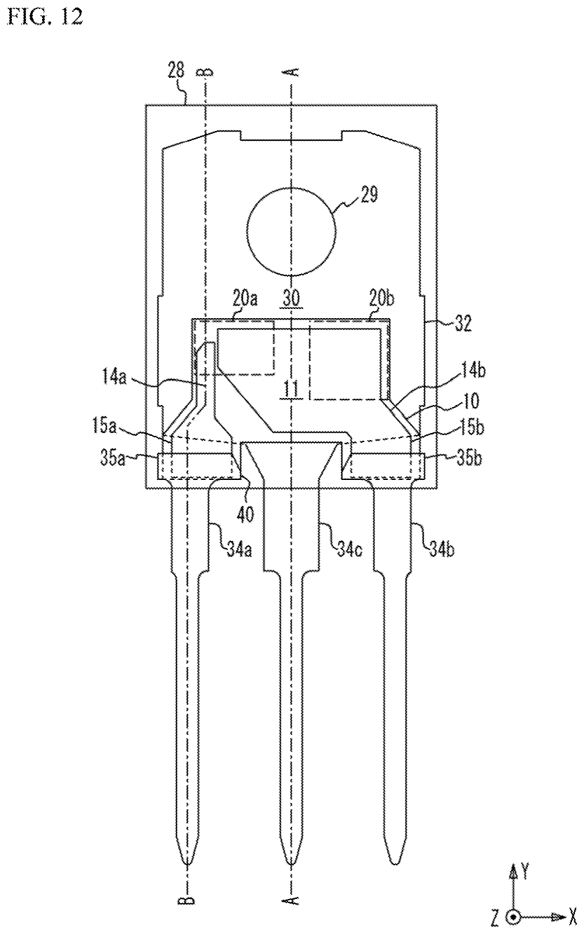

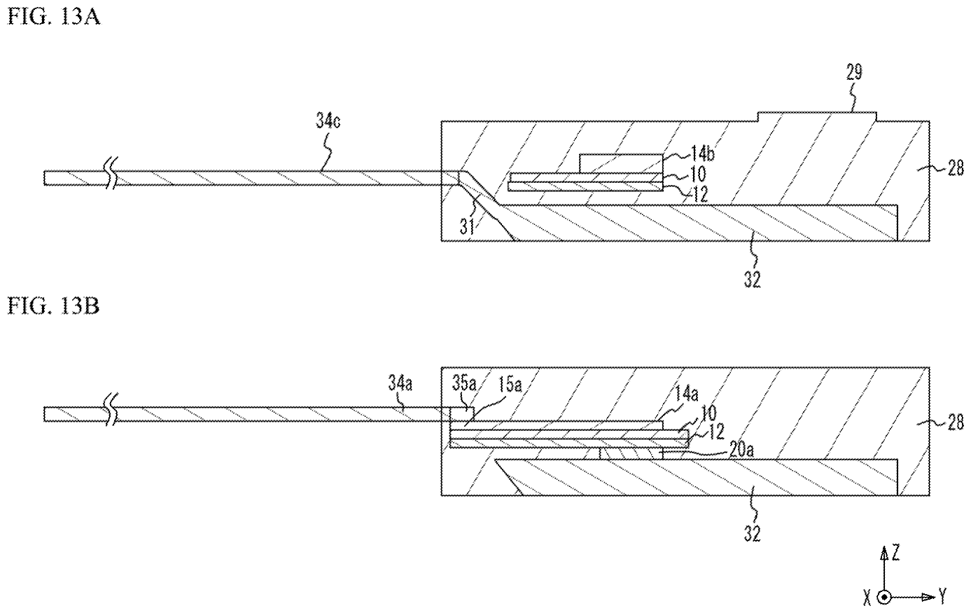

FIG. 12 is a plan view of the module of the first embodiment, FIG. 13A is a cross-sectional view taken along line A-A in FIG. 12, and FIG. 13B is a cross-sectional view taken along line B-B in FIG. 12. As illustrated in FIG. 12 through FIG. 13B, the sealing resin 28 is located on the die pad 32. The sealing resin 28 seals the insulating layer 10 and the electronic components 20a and 20b. The leads 34a through 34c extend from the sealing resin 28 in the negative Y direction. The lead 34c is connected to the die pad 32 through the connection portion 31. The leads 34a and 34b are not connected to the die pad 32, and are electrically connected to the wiring lines 14a and 14b. The lead 34a is electrically connected to the gate terminal of the electronic component 20a. The lead 34b is electrically connected to the source terminal of the electronic component 20a and the anode terminal of the electronic component 20b. The lead 34c is electrically connected to the drain terminal of the electronic component 20a and the cathode terminal of the electronic component 20b. The resin seal gate trace 29 is formed on the upper surface of the sealing resin 28. The resin seal gate trace 29 is located in the positive Y direction relative to the electronic components 20a and 20b. When the gate 51 is provided as illustrated in FIG. 11A, the resin seal gate trace 29 is formed on the positive Y direction surface of the sealing resin 28, and when the gate 51 is provided as illustrated in FIG. 11A, the resin seal gate trace 29 is formed on the negative Z direction surface of the sealing resin 28.

If the insulating layer 10 moves with respect to the lead frame 30 when the pads 15a and 15b are respectively bonded to the frame pads 35a and 35b, a bonding defect may be caused.

In the first embodiment, as illustrated in FIG. 1D and FIG. 3B, the electronic components 20a and 20b are mounted on the lower surface of the insulating layer 10, the wiring lines 14a and 14b penetrating through the insulating layer 10 and connecting to the electronic components 20a and 20b are located on the upper surface of the insulating layer 10. As illustrated in FIG. 5, the ends of the leads 34a and 34b (i.e., the frame pads 35a and 35b) are inserted into the openings 17a and 17b penetrating through the insulating layer 10. As illustrated in FIG. 7B, the ends of the leads 34a and 34b are bonded to the wiring lines 14a and 14b (i.e., the pads 15a and 15b) while the ends of the leads 34a and 34b are inserted in the openings 17a and 17b. This inhibits the insulating layer 10 from moving with respect to the leads 34a and 34b. Thus, a bonding defect is inhibited.

### First Variation of the First Embodiment

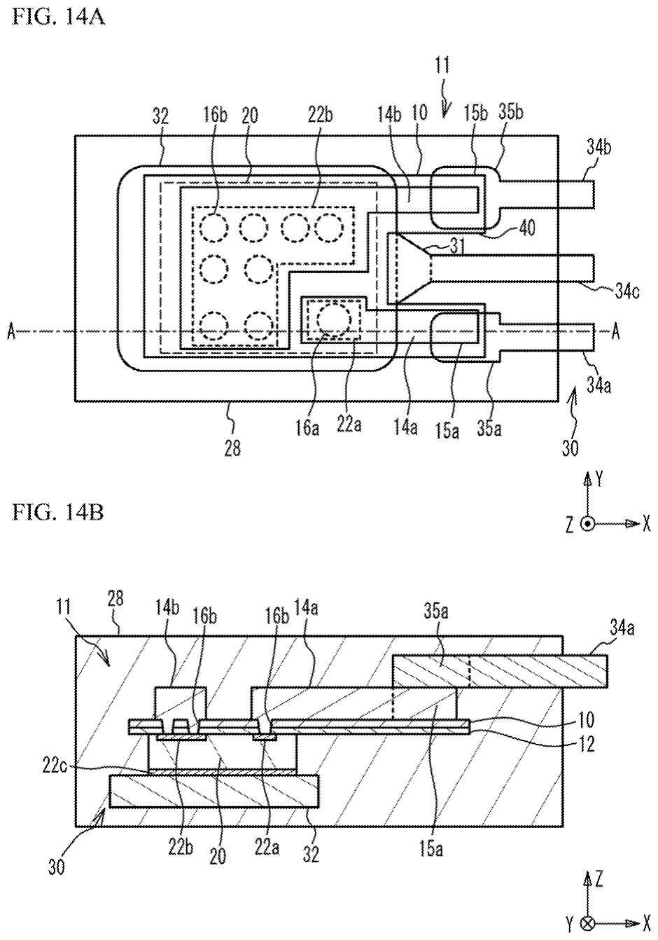

FIG. 14A is a plan view of a module in accordance with a first variation of the first embodiment, and FIG. 14B is a cross-sectional view taken along line A-A in FIG. 14A. As illustrated in FIG. 14A and FIG. 14B, the sheet module 11 is mounted on the lead frame 30. The terminal 22c on the lower surface of an electronic component 20 is bonded to the die pad 32. The wiring lines 14a and 14b are respectively electrically connected to the terminals 22a and 22b through the through holes 16a and 16b penetrating through the insulating layer 10 and the bonding layer 12. The ends of the wiring lines 14a and 14b are the pads 15a and 15b. The upper surfaces of the pads 15a and 15b are bonded to the lower surfaces of the frame pads 35a and 35b in the ends of the leads 34a and 34b. The lead 34c is connected to the die pad 32 through the connection portion 31. Accordingly, the terminals 22a through 22c of the electronic component 20 are respectively electrically connected to the leads 34a through 34c. As described in the first variation of the first embodiment, the number of the electronic components 20 may be one. Other structures are the same as those of the first embodiment, and the description thereof is thus omitted.

### Second Variation of the First Embodiment

FIG. 15A is a cross-sectional view of a module in accordance with a second variation of the first embodiment. As illustrated in FIG. 15A, the leads 34a and 34b are arranged below the insulating layer 10. A protrusion 35d is located on the upper surface of each of the frame pads 35a and 35b. The protrusions 35d are inserted into holes 16d penetrating through the insulating layer 10 and the bonding layer 12, and are bonded to the pads 15a and 15b. By making the tips of the protrusions 35d a cone shape, the protrusions 35d are able to pierce the insulating layer 10 and the bonding layer 12 and are able to be made to be in contact with the pads 15a and 15b. Other structures are the same as those of the first variation of the first embodiment, and the description thereof is thus omitted.

### Third Variation of the First Embodiment

FIG. 15B and FIG. 15C are cross-sectional views of a module in accordance with a third variation of the first embodiment. As illustrated in FIG. 15B and FIG. 15C, the leads 34a and 34b are arranged below the insulating layer 10. The pad 15a and the frame pad 35a are electrically connected through a through hole 16e and a shim 37a. The pad 15b and the frame pad 35b are electrically connected through a through hole 16f and a shim 37b. The shims 37a and 37b are made of a metal material such as, but not limited to, copper. The shims 37a and 37b may be formed of a member different from the frame pads 35a and 35b, or a member integrally formed with the frame pads 35a and 35b. The die pad 32 and the leads 34a through 34c are located in the same plane. Other structures are the same as those of the first variation of the first embodiment, and the description thereof is thus omitted.

### Fourth Variation of the First Embodiment

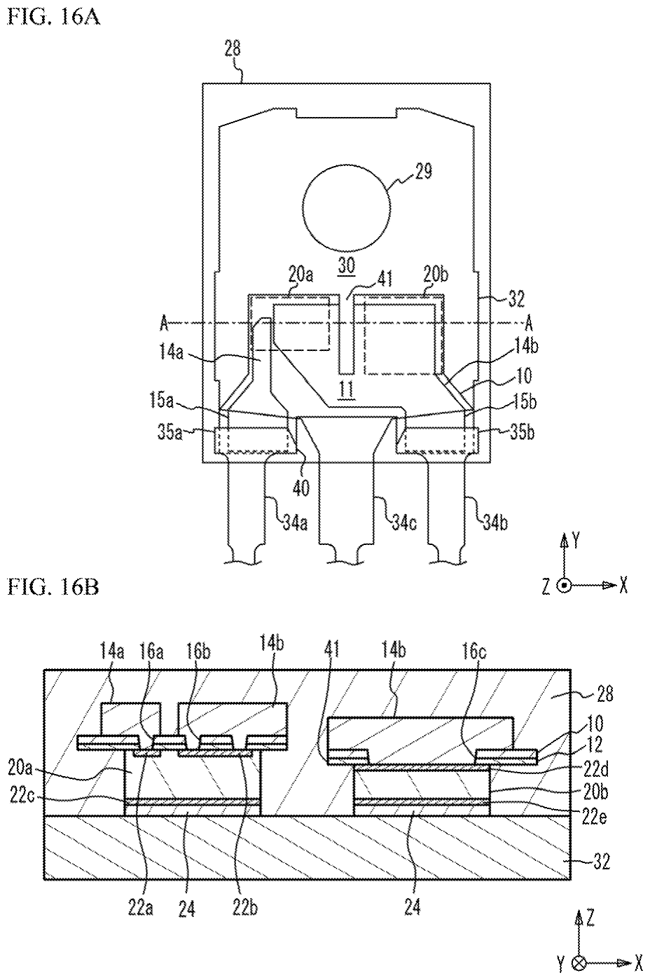

FIG. 16A is a plan view of a module in accordance with a fourth variation of the first embodiment, and FIG. 16B is a cross-sectional view taken along line A-A in FIG. 16A. As illustrated in FIG. 16A and FIG. 16B, the electronic components 20a and 20b have different thicknesses. A slit 41 is provided in the insulating layer 10 between the electronic components 20a and 20b, and thereby, the insulating layer 10 has a forked shape. Other structures are the same as those of the first embodiment, and the description thereof is thus omitted.

When no slit 41 is formed in the insulating layer 10 as in the first embodiment, and the electronic components 20a and 20b having different thicknesses are bonded to the die pad 32, a stress is applied to the insulating layer 10. In addition, when a resin passes between the electronic components 20a and 20b, a load is applied to the insulating layer 10. This may cause peeling of the terminals 22a through 22e of the electronic components 20a and 20b from the wiring lines 14a and 14b or the die pad 32.

In the fourth variation of the first embodiment, the slit 41 is provided in the insulating layer 10 between the electronic components 20a and 20b. This structure reduces a stress applied to the insulating layer 10 even when the electronic components 20a and 20b having different thicknesses are bonded to the die pad 32. In addition, a load is inhibited from being applied to the insulating layer 10 when a resin passes between the electronic components 20a and 20b having identical or different thicknesses. Accordingly, the terminals 22a through 22e of the electronic components 20a and 20b are inhibited from peeling from the wiring lines 14a and 14b or the die pad 32.

The lead frame 30 illustrated in FIG. 4A through FIG. 4C has three leads to which a transistor is mounted. The lower surface of the electronic component 20a is bonded to the die pad 32. The lead 34a (a first lead) includes the frame pad 35a (a first frame pad) located adjacent to the die pad 32, and extends from the frame pad 35a in a direction away from the die pad 32. The lead 34b (a second lead) includes the frame pad 35b (a second frame pad) located adjacent to the die pad 32, and extends from the frame pad 35b in a direction away from the die pad 32. The lead 34c (a third lead) is located between the leads 34a and 34b, and is integrally formed with the die pad 32. The extension directions of the leads 34a, 34b, and 34c are substantially parallel to the extent that allows a manufacturing error.

A bonding wire (a metal thin wire) is used to mount the electronic components 20a and 20b to the above-described lead frame 30 and electrically connect the leads 34a through 34c and the electronic components 20a and 20b. However, the bonding wire is looped upward. To prevent the bonding wire from being exposed from the sealing resin 28, the sealing resin 28 thickens, and thereby, the module increases in size.

In the first embodiment and the variations thereof, the sheet module 11 as illustrated in FIG. 3B is formed. In the sheet module 11, the electronic component 20a is mounted on the lower surface of the insulating layer 10. The wiring line 14a (a first wiring line) and the wiring line 14b (a second wiring line) extend on the upper surface of the insulating layer 10. The wiring line 14a includes the pad 15a (a first pad) in the end thereof, and is electrically connected to the electronic component 20a through the through hole 16a (a first through hole) penetrating through the insulating layer 10. The wiring line 14b includes the pad 15b (a second pad) in the end thereof, and is electrically connected to the electronic component 20a through the through hole 16b (a second through hole) penetrating through the insulating layer 10. The pad 15a is bonded to the frame pad 35a, and the pad 15b is bonded to the frame pad 35b. This structure allows the sealing resin 28 to be thin, and thus decreases the size of the module.

In addition, the cutout 40 is provided in the insulating layer 10 between the frame pad 35a and the lead 34c and/or the insulating layer 10 between the frame pad 35b and the lead 34c. This structure reduces the load applied to the insulating layer 10 in the space 55 when the resin 27 is injected as illustrated in FIG. 10 through FIG. 11C.

As illustrated in FIG. 14B in the first variation of the first embodiment, the upper surface of the pad 15a is bonded to the lower surface of the frame pad 35a, and the upper surface of the pad 15b is bonded to the lower surface of the frame pad 35b. Since the pads 15a and 15b are located on the upper surface of the insulating layer 10, the pads 15a and 15b can be easily bonded to the frame pads 35a and 35b.

As illustrated in FIG. 15A through FIG. 15C of the second and third variations of the first embodiment, the lower surface of the pad 15a is bonded to the upper surface of the frame pad 35a, and the lower surface of the pad 15b is bonded to the upper surface of the frame pad 35b. This structure allows the leads 34a and 34b to be located at the side at which the die pad 32 is also located with respect to the insulating layer 10. Thus, the module is reduced in size.

As illustrated in FIG. 15B and FIG. 15C in the third variation of the first embodiment, the lower surface of the pad 15a is bonded to the upper surface of the frame pad 35a through the shim 37a (a first shim), and the lower surface of the pad 15b is bonded to the upper surface of the frame pad 35b through the shim 37b (a second shim). This structure reduces the bend between the leads 34a through 34c and the die pad 32.

As described in the first through third variations of the first embodiment, the sheet module 11 may include one electronic component 20, or as described in the first embodiment and the fourth variation thereof, the sheet module 11 may include a plurality of the electronic components 20a and 20b.

The electronic components 20, 20a, and 20b are power semiconductor elements, and the insulating layer 10 is formed of a polyimide sheet. Polyimide has a heat resistance, and the lead frame 30 has high heat release performance. Thus, the current flowing through the power semiconductor element can be increased.

As illustrated in FIG. 3B, prepared is the sheet module 11 including the insulating layer 10. The electronic components 20a and 20b are mounted on the lower surface of the insulating layer 10, the wiring lines 14a and 14b connected to the electronic components 20a and 20b are located on the upper surface of the insulating layer 10. The insulating layer 10 has the openings 17a and 17b located adjacent to the ends of the wiring lines 14a and 14b. As illustrated in FIG. 5 through FIG. 7B, the frame pads 35a and 35b located in the ends of the leads 34a and 34b are inserted into the openings 17a and 17b. As illustrated in FIG. 8A and FIG. 9, the frame pads 35a and 35b are electrically connected to the wiring lines 14a and 14b while the frame pads 35a and 35b in the ends of the leads 34a and 34b are inserted in the openings 17a and 17b. Accordingly, the insulating layer 10 is inhibited from moving with respect to the leads 34a and 34b. Thus, a bonding defect is inhibited.

The step of inserting the frame pads 35a and 35b, which are located in the ends of the leads 34a and 34b, into the openings 17a and 17b includes a step of preparing the lead frame 30 including the die pad 32, to which the lower surfaces of the electronic components 20a and 20b are to be bonded, and the leads 34a and 34b, and a step of fixing the sheet module 11 to the lead frame 30 while the frame pads 35a and 35b are inserted in the openings 17a and 17b. This inhibits a bonding effect.

As illustrated in FIG. 3B, prepared is the sheet module 11 including the insulating layer 10 in which the cutout 40 is provided between the pad 15a of the wiring line 14a and the pad 15b of the wiring line 14b. As illustrated in FIG. 5 through FIG. 7B, the sheet module 11 is fixed to the lead frame 30. As illustrated in FIG. 10 through FIG. 11C, the sheet module 11 and the lead frame 30 are resin-sealed. The melted resin 27 passes through the cutout 40 in the step of resin-sealing. Thus, the load on the insulating layer 10 due to the resin 27 is reduced.

As illustrated in FIG. 11A and FIG. 11B, in the step of resin-sealing, used are the upper mold 50 and the lower mold 52 (a mold) to which the gate 51, through which the resin 27 is injected, is provided such that the melted resin 27 flows in the direction parallel to the upper surface of the die pad 32 and/or the direction from the lower surface to the upper surface of the die pad 32. This inhibits the pads 15a and 15b from peeling from the frame pads 35a and 35b.

As illustrated in FIG. 16A and FIG. 16B of the fourth variation of the first embodiment, in the sheet module 11, the electronic component 20a (a first electronic component) and the electronic component 20b (a second electronic component) are mounted on the lower surface of the insulating layer 10. The wiring line 14a is electrically connected to the electronic component 20a through the through hole 16a, and the wiring line 14b is electrically connected to the electronic component 20a and/or 20b through the through hole 16b and/or 16c. The slit 41 is provided to the insulating layer 10 between the above-described electronic components 20a and 20b. Accordingly, a stress is inhibited from being applied to the insulating layer 10. Thus, the electronic components 20a and 20b are inhibited from peeling from the wiring lines 14a and 14b, or the die pad 32.

### Fifth Variation of the First Embodiment

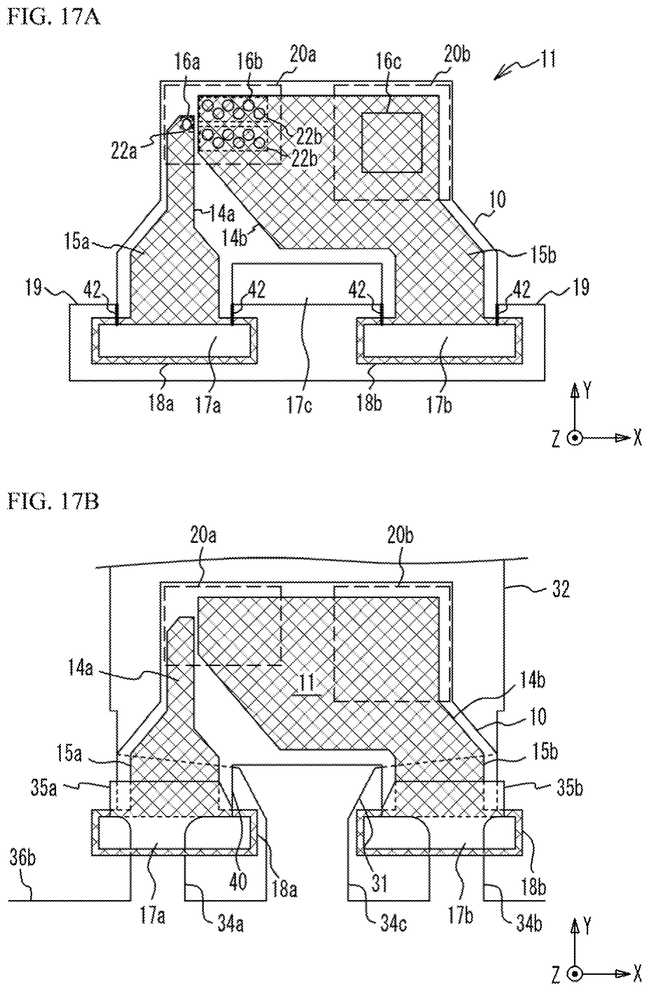

FIG. 17A is a plan view of a sheet module in accordance with a fifth variation of the first embodiment. As illustrated in FIG. 17A, in the sheet module 11 in the fifth variation of the first embodiment, metal layers 18a and 18b are provided to the ends of the pads 15a and 15b so as to surround the openings 17a and 17b, respectively. The metal layers 18a and 18b are made of the same material as the pads 15a and 15b, and are formed at the same time as the wiring lines 14a and 14b. Thus, the pad 15a and the metal layer 18a are interconnected and are integrally formed, and the pad 15b and the metal layer 18b are interconnected and are integrally formed. Other structures are the same as those illustrated in FIG. 3B of the first embodiment, and the description thereof is thus omitted.

FIG. 17B is a plan view illustrating a method of manufacturing the module in accordance with the fifth variation of the first embodiment. As illustrated in FIG. 17B, as in FIG. 6 through FIG. 8B, the frame pads 35a and 35b are respectively inserted into the openings 17a and 17b, and the pads 15a and 15b are respectively bonded to the frame pads 35a and 35b. Thereafter, the four regions 42 of the insulating layer 10 in FIG. 17A are cut by a laser beam, a die cutting device, or a cutter. Accordingly, the cutout 40 is formed between the pads 15a and 15b. The metal layers 18a and 18b respectively having the openings 17a and 17b remain at the ends of the pads 15a and 15b, respectively, and the frame pads 35a and 35b are respectively inserted into the openings 17a and 17b. Other structures are the same as those illustrated in FIG. 9 of the first embodiment, and the description thereof is thus omitted.

### Sixth Variation of the First Embodiment

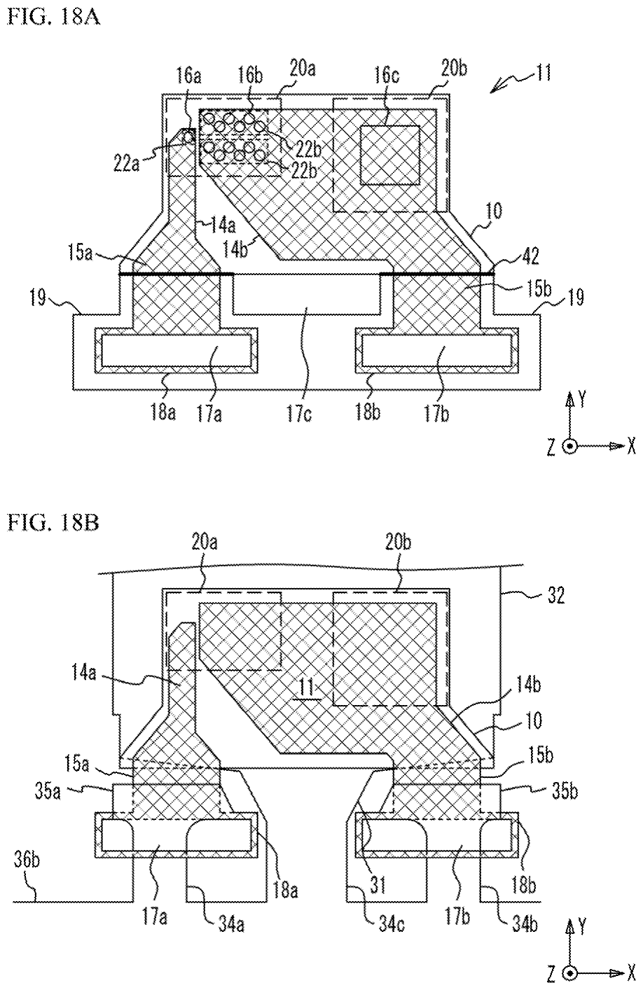

FIG. 18A is a plan view of a sheet module in accordance with a sixth variation of the first embodiment. As illustrated in FIG. 18A, in the sheet module 11 in the sixth variation of the first embodiment, two regions 42 are located substantially in line with the positive Y direction edge of the opening 17c. Other structures are the same as those illustrated in FIG. 17A in the fifth variation of the first embodiment, and the description thereof is thus omitted.

FIG. 18B is a plan view illustrating a method of manufacturing the module in accordance with the sixth variation of the first embodiment. As illustrated in FIG. 18B, the two regions 42 of the insulating layer 10 in FIG. 18A are cut with use of a laser beam, a die cutting device, or a cutter. Thus, the cutout 40 is not formed, and the pads 15a and 15b and the metal layers 18a and 18b extend from the insulating layer 10 to the outside of the insulating layer 10. The frame pads 35a and 35b are inserted in the openings 17a and 17b of the metal layers 18a and 18b, respectively. Other structures are the same as those illustrated in FIG. 17B of the fifth variation of the first embodiment, and the description thereof is thus omitted.

### Seventh Variation of the First Embodiment

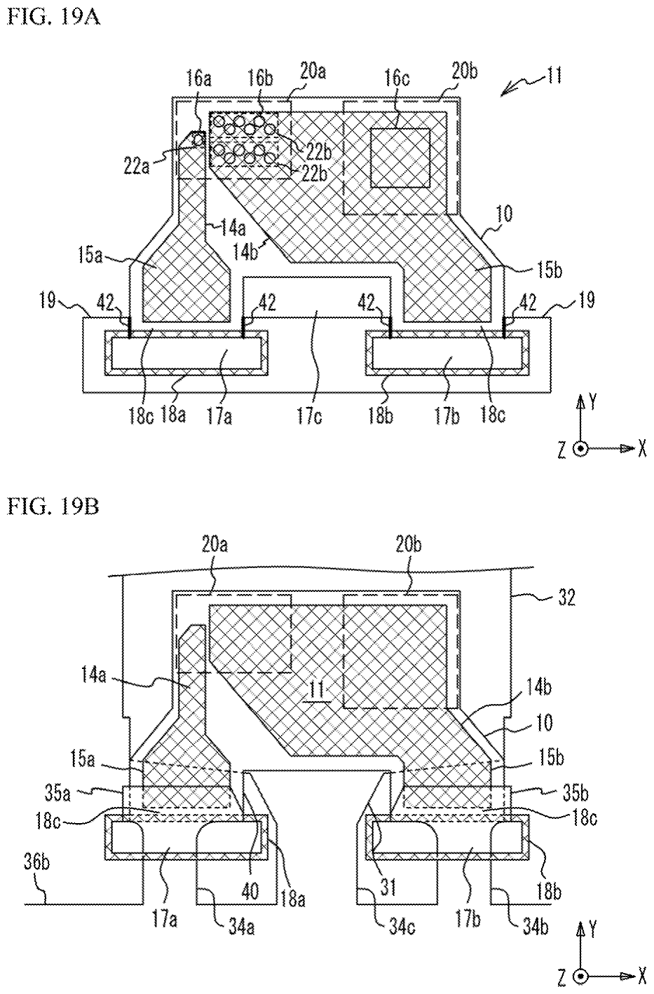

FIG. 19A is a plan view of a sheet module in accordance with a seventh variation of the first embodiment. As illustrated in FIG. 19A, in the sheet module 11 in the seventh variation of the first embodiment, the pads 15a and 15b are respectively separated from the metal layers 18a and 18b through spaces 18c. The pads 15a and 15b and the metal layers 18a and 18b may be made of the same material, or may be made of different materials. Other structures are the same as those illustrated in FIG. 17A of the fifth variation of the first embodiment, and the description thereof is thus omitted.

FIG. 19B is a plan view illustrating a method of manufacturing the module in accordance with the seventh variation of the first embodiment. As illustrated in FIG. 19B, the four regions 42 of the insulating layer 10 in FIG. 19A are cut with use of a laser beam, a die cutting device, or a cutter. Thus, the cutout 40 is formed between the pads 15a and 15b. The metal layers 18a and 18b are respectively bonded to the ends of the pads 15a and 15b through the insulating layer 10. Accordingly, the metal layers 18a and 18b are left. The frame pads 35a and 35b are respectively inserted in the openings 17a and 17b of the metal layers 18a and 18b. Other structures are the same as those illustrated in FIG. 17B of the fifth variation of the first embodiment, and the description thereof is thus omitted.

### Eighth Variation of the First Embodiment

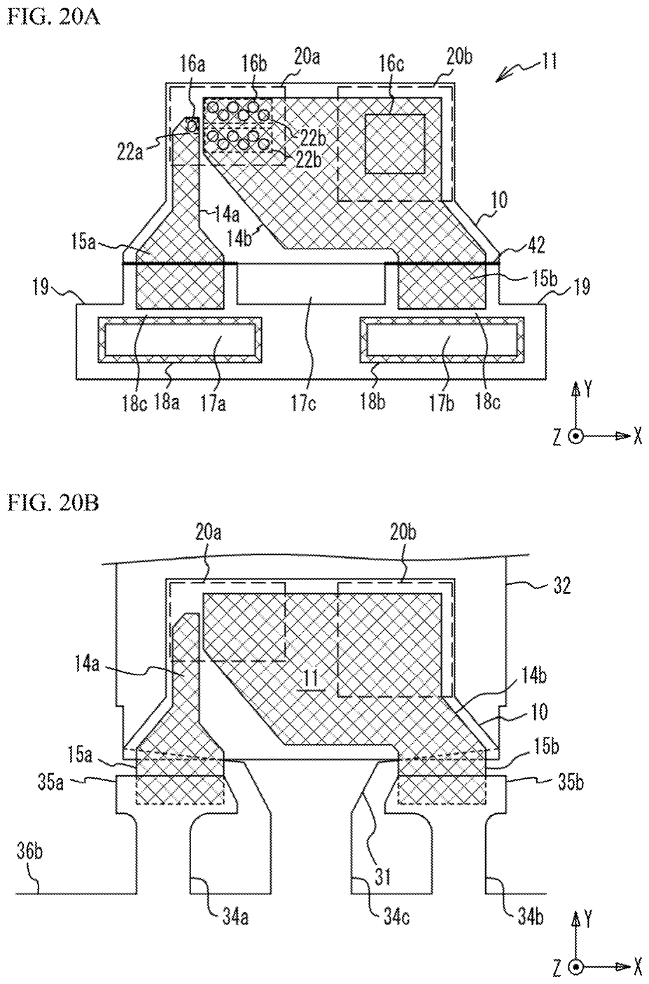

FIG. 20A is a plan view of a sheet module in an eighth variation of the first embodiment. As illustrated in FIG. 20A, in the sheet module 11 in the eighth variation of the first embodiment, two regions 42 are located substantially in line with the positive Y direction edge of the opening 17c. Other structures are the same as those illustrated in FIG. 19A of the sixth variation of the first embodiment, and the description thereof is thus omitted.

FIG. 20B is a plan view illustrating a method of manufacturing the module in the eighth variation of the first embodiment. As illustrated in FIG. 20B, the two regions 42 of the insulating layer 10 in FIG. 20A are cut with use of a laser beam, a die cutting device, or a cutter. Thus, the cutout 40 is not formed, and the pads 15a and 15b extend from the insulating layer 10 to the outside of the insulating layer 10. The metal layers 18a and 18b are separated from the pads 15a and 15b, respectively. Other structures are the same as those illustrated in FIG. 19B of the sixth variation of the first embodiment, and the description thereof is thus omitted.

As in the fifth through eighth variations of the first embodiment, when the frame pads 35a and 35b are respectively inserted into the openings 17a and 17b, the metal layers 18a and 18b are located on the insulating layer 10 so as to respectively surround the openings 17a and 17b. That is, the metal layers 18a and 18b are located on the insulating layer 10 so as to surround the openings 17a and 17b adjacent to the pads 15a and 15b, respectively. Thus, even when the insulating layer 10 has a flexibility, the metal layers 18a and 18b reinforce the insulating layer 10. Thus, the insertion of the frame pads 35a and 35b into the openings 17a and 17b becomes easier.

The widths of the metal layers 18a and 18b are preferably less than the smallest widths of the openings 17a and 17b. This allows the size reduction of the sheet module. To reinforce the insulating layer 10 by the metal layers 18a and 18b, the distance between the metal layer 18a and the opening 17a and the distance between the metal layer 18b and the opening 17b are preferably less than the smallest widths of the openings 17a and 17b. The width of the space 18c between the metal layer 18a and the pad 15a and the width of the space 18c between the metal layer 18b and the pad 15b are preferably less than the smallest widths of the openings 17a and 17b.

In the fifth and sixth variations of the first embodiment, the pads 15a and 15b are respectively connected to the metal layers 18a and 18b. Thus, parts of the metal layers 18a and 18b are respectively bonded to the frame pads 35a and 35b in addition to the pads 15a and 15b. Thus, the bond strength is increased.

In the seventh and eighth variations of the first embodiment, the pads 15a and 15b are respectively separated from the metal layers 18a and 18b. Thus, when the frame pads 35a and 35b are inserted into the openings 17a and 17b, respectively, the metal layers 18a and 18b easily move with respect to the pads 15a and 15b, respectively. Thus, the openings 17a and 17b freely move when the frame pads 35a and 35b are inserted into the openings 17a and 17b. Accordingly, the frame pads 35a and 35b are more easily inserted into the openings 17a and 17b, respectively.

In the fifth and seventh variations of the first embodiment, the widths of the metal layers 18a and 18b in the regions 42 are small. In the sixth and eighth variations of the first embodiment, the widths of the pads 15a and 15b in the regions 42 are large. When the metal layer is bonded to the region in which the insulating layer 10 is to be cut, the cutting of the insulating layer 10 becomes difficult. Thus, in the fifth and seventh variations of the first embodiment, the cutting of the insulating layer 10 in the region 42 is easier than in the sixth and eighth variations of the first embodiment.

In the sixth and eighth variations of the first embodiment, no insulating layer 10 is located at the ends of the pads 15a and 15b. Thus, as illustrated in FIG. 11A through FIG. 11B, the flow of a resin is inhibited from being disturbed by the insulating layer 10 at the time of resin-sealing. In the eighth variation of the first embodiment, the metal layers 18a and 18b are not provided at the ends of the pads 15a and 15b. Thus, the flow of a resin is inhibited from being disturbed by the metal layers 18a and 18b at the time of resin-sealing.

The first embodiment and the variations thereof have described power modules including a power semiconductor element. However, the module may be a module including an electronic component other than a power semiconductor element.

### Second Embodiment

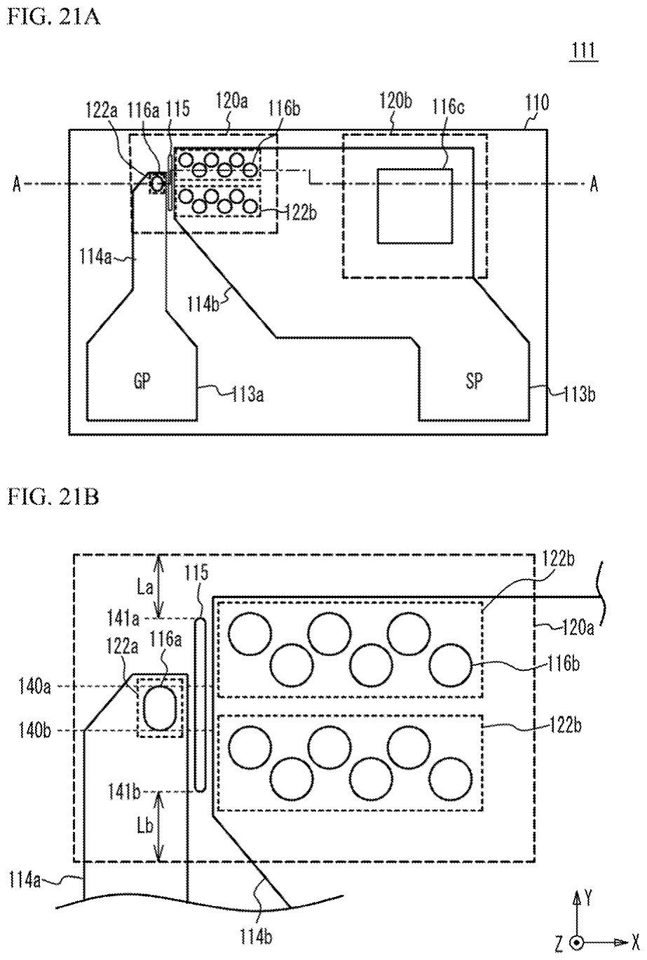

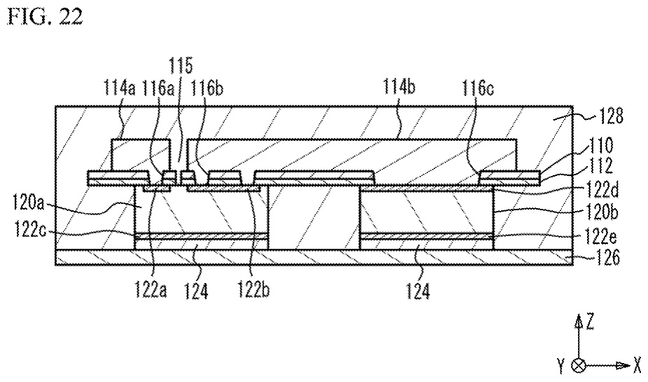

FIG. 21A is a plan view of a sheet module in accordance with a second embodiment, and FIG. 21B is an enlarged view of a part around the electronic component in FIG. 21A. FIG. 22 is a cross-sectional view taken along line A-A in FIG. 21A. In the planar directions of an insulating layer 110, the direction from a terminal 122a to a terminal 122b is defined as an X direction, the direction perpendicular to the X direction is defined as a Y direction, and the thickness direction of the insulating layer 110 is defined as a Z direction. FIG. 21A and FIG. 21B illustrate the insulating layer 110, wiring lines 114a and 114b, an opening 115, through holes 116a through 116c, electronic components 120a and 120b, and the terminals 122a and 122b. In FIG. 21A and FIG. 21B, illustrated are the through holes 116a through 116c under the configuration where the number of the through holes 116a is one, the number of the through holes 116b is twelve, and the number of the through holes 116c is one. In FIG. 22, illustrated are the through holes 116a through 116c under the configuration where the number of the through holes 116b is two. However, the numbers of the through holes 116a through 116c are freely selected. For example, the number of the through holes 116a and the number of the through holes 116c may be two or more, and the number of the through holes 116b may be one.

As illustrated in FIG. 21A through FIG. 22, a bonding layer 112 is located on the lower surface of the insulating layer 110. The insulating layer 110 is a resin insulating layer having a flexibility such as a polyimide layer. The electronic components 120a and 120b are mounted on the lower surface of the bonding layer 112. The bonding layer 112 is formed of a resin adhesive agent such as, but not limited to, an epoxy resin adhesive agent, and bonds the insulating layer 110 and the electronic components 120a and 120b. The insulating layer 110 has a thickness of, for example, 20 μm to 50 μm. The thickness of the bonding layer 112 is, for example, 5 μm to 20 μm, and is less than the thickness of the insulating layer 110.

The electronic components 120a and 120b are power elements, and are transistors such as insulated gate bipolar transistors (IGBTs), bipolar transistors, or field effect transistors (FETs) or diodes. A semiconductor such as Si, GaN, or SiC is used in the transistor or the diode. The electronic components 120a and 120b in a bare chip state are mounted on the insulating layer 110. The electronic components 120a and 120b may be packages in which a bare chip is sealed and mounted. In FIG. 21A and FIG. 22, the electronic component 120a is a bare chip of a vertical SiC transistor in which a current flows between the upper surface and the lower surface. The electronic component 120b is a vertical diode in which a current flows between the upper surface and the lower surface.

The terminals 122a and 122b are located on the upper surface of the electronic component 120a, and the terminal 122c is located on the lower surface of the electronic component 120a. The terminals 122a, 122b, and 122c are respectively a gate terminal, a source terminal, and a drain terminal. The terminal 122d is located on the upper surface of the electronic component 120b, and the terminal 122e is located on the lower surface of the electronic component 120b. The terminals 122d and 122e are respectively an anode terminal and a cathode terminal. The terminals 122a through 122e are formed in advance in the step of manufacturing the electronic components 120a and 120b, and are formed of a metal layer made of, for example, copper, gold, or aluminum.

The through holes 116a through 116c penetrating through the insulating layer 110 and the bonding layer 112 are provided. One through hole 116a is provided, and six through holes 116b are provided for each of the two terminals 122b. A large current flows through the source terminal and the drain terminal. The gate terminal is a control terminal. Thus, a large electric current does not flow through the gate terminal. Thus, the terminal 122a is smaller than the terminal 122b. In addition, the total area of the through hole 116a is less than the total area of the through holes 116b. The through holes 116a through 116c have dimensions of, for example, 30 μm to 500 μm.

The wiring lines 114a and 114b are located on the inner surfaces of the through holes 116a through 116c and the surface of the insulating layer 110. The wiring line 114a is electrically connected to the terminal 122a (a gate terminal) through the through hole 116a. The wiring line 114b is electrically connected to the terminal 122b (a source terminal) through the through holes 116b, and is electrically connected to the terminal 122d (an anode terminal) through the through hole 116c. The wiring lines 114a and 114b are conductive patterns formed of a metal layer such as a copper layer. The thicknesses of the wiring lines 114a and 114b are, for example, 50 μm to 300 μm, and are larger than the thickness of the insulating layer 110 because a large current flows through the wiring lines 114a and 114b. The thicknesses of the wiring lines 114a and 114b may be as thin as approximately 10 μm. Two pads 113a and 113b are located adjacent to the lower-side edge of the insulating layer 110, and the wiring lines 114a and 114b respectively extend from the pad 113a (a gate pad GP) and the pad 113b (a source pad SP) toward the upper-side edge of the insulating layer 110. The part connected to the gate terminal and the source terminal is typically referred to as a pad. However, in this description, a whole of a conductive pattern including the pad is referred to as a wiring line.

A metal layer 126 is located below the electronic components 120a and 120b. The metal layer 126 is electrically connected to the terminal 122c (a drain terminal) and the terminal 122e (a cathode terminal) through a bonding layer 124. The bonding layer 124 is formed of, for example, a metal paste such as a copper paste or a silver paste or a conductive bonding layer such as solder. The metal layer 126 is a metal layer mainly made of, for example, copper, aluminum, or gold, and is a die pad referred to as an island to which a transistor chip in a lead frame employed for a transistor package is bonded. A ground potential is supplied to the metal layer 126. The examples of the metal layer 126 will be described later. A sheet in which the wiring lines 114a and 114b and the electronic components 120a and 120b are provided to the insulating layer 110 before a sealing resin is provided is referred to as a sheet module 111.

A sealing resin 128 is located on the metal layer 126 so as to cover the electronic components 120a and 120b, the insulating layer 110, and the wiring lines 114a and 114b. The sealing resin 128 is a thermosetting resin or a thermoplastic resin, and is, for example, an epoxy resin or a phenolic resin.

The opening 115 penetrating through the insulating layer 110 and the bonding layer 112 is provided between the terminals 122a and 122b. This opening 115 has a slit shape. The width of the opening 115 in the X direction is, for example, 5 μm to 50 μm, and the length of the opening 115 in the Y direction is, for example, 100 μm or greater.

In the through hole 116a, the area where the terminal 122a and the wiring line 114a are in contact with each other is small. Thus, due to the difference in thermal expansion coefficient among the insulating layer 110, the wiring line 114a, and the metal layer 126, a load is applied to the through hole 116a, and thereby, the connection portion cracks and/or a film peels. Provision of the opening 115 (a slit) to inhibit them reduces the stress.

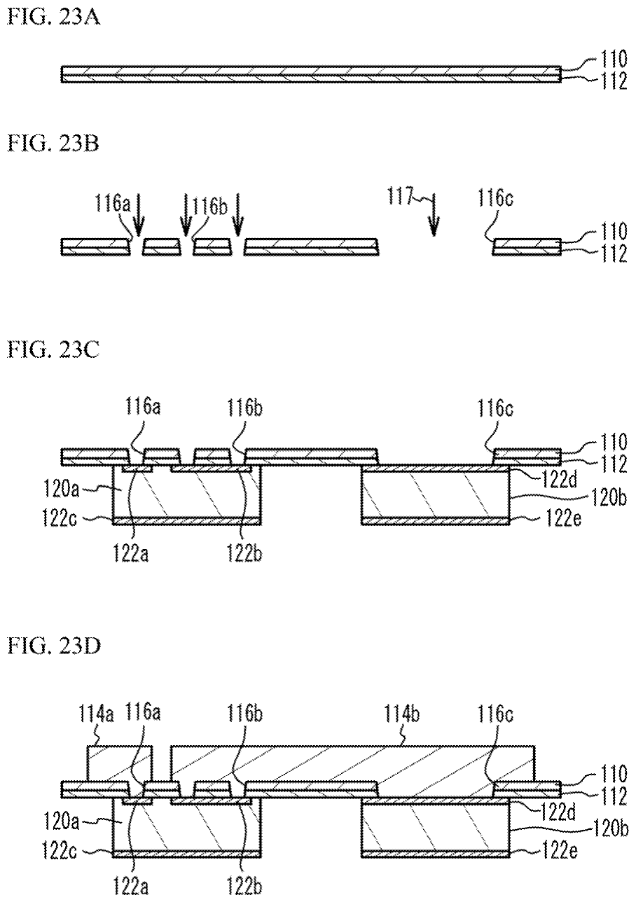

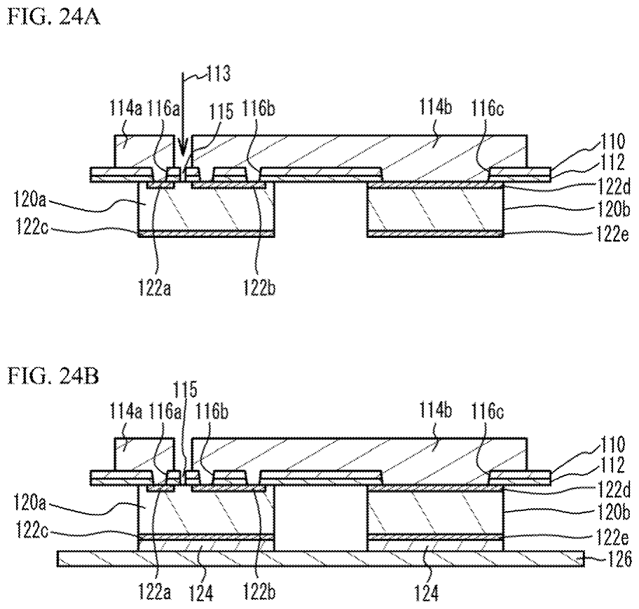

FIG. 23A through FIG. 24B are cross-sectional views illustrating a method of manufacturing the module of the second embodiment. As illustrated in FIG. 23A, the bonding layer 112 is applied onto the lower surface of the insulating layer 110. The bonding layer 112 is applied by, for example, spin coating, spray coating, or ink jetting. The insulating layer 110 on which the bonding layer 112 is formed in advance may be prepared. It is not necessary to form the bonding layer 112 across the entire area of the insulating layer 110. The bonding layer 112 may be formed only in regions where the electronic components 120a and 120b are to be mounted.

As illustrated in FIG. 23B, the through holes 116a through 116c penetrating through the insulating layer 110 and the bonding layer 112 are formed. The through holes 116a through 116c are formed by irradiating the insulating layer 110 and the bonding layer 112 with a laser beam 117 of, for example, an ultraviolet light, a visible light, or an infrared light.

As illustrated in FIG. 23C, the electronic components 120a and 120b are temporarily bonded onto the lower surface of the bonding layer 112. Thereafter, the bonding layer 112 is hardened by heat treatment to bond the electronic components 120a and 120b and the insulating layer 110. This process fixes the electronic components 120a and 120b to the insulating layer 110. The heat treatment is conducted at a temperature of, for example, 200° C. to 300° C. In this state, the terminals 122a, 122b, and 122d of the electronic components 120a and 120b are exposed to the through holes 116a, 116b, and 116c, respectively. It is not necessary to conduct laser processing in FIG. 23B. The through holes 116a through 116c may be formed after the electronic components 120a and 120b are bonded to and fixed to the insulating layer 110. However, in this case, a thermal load due to a laser beam is applied to the electronic components 120a and 120b. Thus, it is preferable that the through holes 116a through 116c are formed before the electronic components 120a and 120b are mounted on the insulating layer 110.

As illustrated in FIG. 23D, the wiring lines 114a and 114b are formed on the upper surface of the insulating layer 110 and the inner surfaces of the through holes 116a through 116c. A method of forming the wiring lines 114a and 114b will be described. A seed layer is formed on the upper surface of the insulating layer 110 and the inner surfaces of the through holes 116a and 116b. The seed layer is formed by, for example, sputtering. The seed layer is a metal layer including, for example, a titanium layer and a copper layer stacked in this order from the insulating layer 110 side. Then, a plated layer is formed on the upper surface of the seed layer by electrolytic plating. The plated layer is a metal layer such as, but not limited to, a copper layer. The plated layer is formed by electrolytic plating supplying a current to the seed layer. The seed layer and the plated layer form the wiring lines 114a and 114b. The plated layer may be patterned by photolithography and etching after the plated layer is formed across the entire surface of the insulating layer 110. Alternatively, the wiring lines 114a and 114b may be formed as follows. Photoresist having openings in the regions where the wiring lines 114a and 114b are to be formed is formed on the insulating layer 110 by photolithography. Thereafter, the plated layer is formed in the openings of the photoresist.

As illustrated in FIG. 24A, the opening 115 penetrating through the insulating layer 110 and the bonding layer 112 is formed. The opening 115 is formed by irradiating the insulating layer 110 and the bonding layer 112 with a laser beam 113 of, for example, an ultraviolet light, a visible light, or an infrared light. The opening 115 may be formed at the same time as the through holes 116a through 116c are formed in FIG. 23B. When the opening 115 is formed after the electronic components 120a and 120b are mounted on the insulating layer 110, a heat is applied to the electronic components 120a and 120b, and the electronic components 120a and 120b may thereby deteriorate. When the opening 115 is formed at the same time as the through holes 116a through 116c are formed, the deterioration of the electronic components 120a and 120b is inhibited. When the opening 115 is formed in FIG. 23B, a plating solution may penetrate to the side at which the electronic components 120a and 120b are to be mounted of the insulating layer 110 through the opening 115 in FIG. 23C, and thereby, a plated layer may be formed. To inhibit the above-described trouble, the opening 115 may be covered with photoresist or a film before the wiring lines 114a and 114b are formed. The opening 115 may be formed by cutting a slash with use of a cutter.

As illustrated in FIG. 24B, the terminals 122c and 122e are bonded to the metal layer 126. The terminals 122c and 122e are bonded to the metal layer 126 as follows, for example. The bonding layer 124 is applied onto the lower surfaces of the terminals 122c and 122e and the upper surface of the metal layer 126. The bonding layer 124 is formed of solder or a conductive paste, and is formed by, for example, printing, spin coating, spray coating, or ink jetting. Then, the bonding layer 124 is made to be in contact with the terminals 122c and 122e and the metal layer 126, and the bonding layer 124 is baked by heat treatment to bond the terminals 122c and 122e to the metal layer 126. This causes the terminals 122c and 122e and the metal layer 126 to be thermally, mechanically, electrically fixed to each other. The heat treatment temperature is, for example, approximately 180° C. to 300° C., and is a temperature at which the insulating layer 110 and the bonding layer 112 are not softened. Thereafter, the sealing resin 128 may be formed. Through the above-described process, the module of the second embodiment is completed.

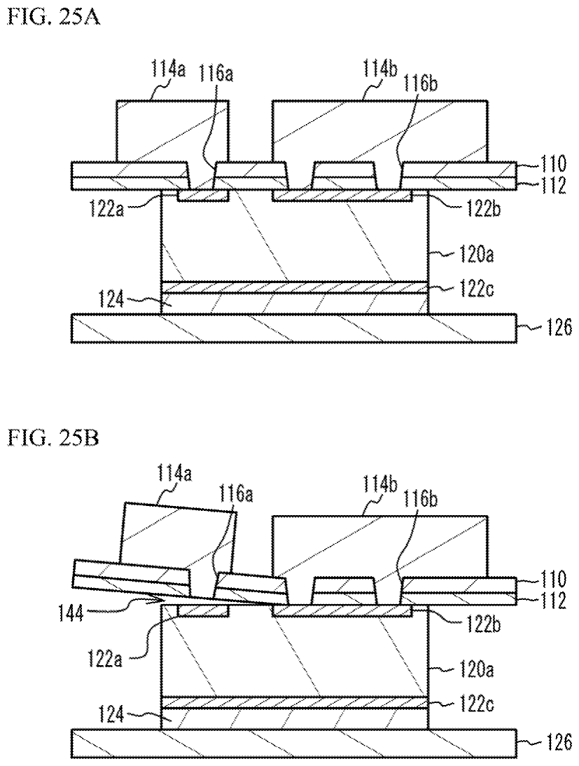

FIG. 25A and FIG. 25B are cross-sectional views of a module in accordance with a first comparative example. As illustrated in FIG. 25A, in the first comparative example, the insulating layer 110 and the bonding layer 112 have no opening 115. When a large current flows through the electronic component 120a as illustrated in FIG. 25B, the electronic components 120a and 120b and the wiring lines 114a and 114b generate heat. At this time, due to the difference in thermal expansion coefficient among members, the insulating layer 10 warps in whole. In the first comparative example, the linear thermal expansion coefficients of the insulating layer 110 and the bonding layer 112 made of a resin are greater than the linear thermal expansion coefficients of the wiring lines 114a and 114b formed of a copper layer. Thus, the insulating layer 110 and the bonding layer 112 warp so that their upper surfaces recess, and their lower surfaces protrude. As the temperature of the bonding layer 112 made of a resin increases, the bonding force of the bonding layer 112 becomes weak. In particular, since the area of contact between the terminal 122a and the wiring line 114a is small, the bonding force is weak. Therefore, the wiring line 114a may peel from the terminal 122a as in a part 144, or the wiring line 114a in the through hole 116a may crack. This leads to the disconnection between the terminal 122a and the wiring line 114a or a high resistance between the terminal 122a and the wiring line 114a, and a poor connection may occur.

In the second embodiment, the electronic component 120a (a first electronic component) includes the terminal 122a (a first terminal) and the terminal 122b (a second terminal) on the upper surface of the electronic component 120a, and is mounted on the lower surface of the insulating layer 110 (a resin insulating layer). The bonding layer 112 (a resin bonding layer) bonds the lower surface of the insulating layer 110 and the upper surface of the electronic component 120a. The wiring line 114a (a first wiring line) is located on the inner surface of at least one through hole 116a (a first through hole) penetrating through the insulating layer 110 and the bonding layer 112 and the upper surface of the insulating layer 110, and is connected to the terminal 122a. The wiring line 114b (a second wiring line) is located on the inner surface of at least one through hole 116b (a second through hole) penetrating through the insulating layer 110 and the bonding layer 112 and the upper surface of the insulating layer 110, and is connected to the terminal 122b. No metal layer such as a terminal and/or a wiring line is located between the terminals 122a and 122b and between the wiring line 114a and the wiring line 114b.

In the above-described module, the opening 115 penetrating through the insulating layer 110 and the bonding layer 112 is located between the terminals 122a and 122b and between the wiring line 114a and the wiring line 114b. Thus, the stress of the insulating layer 110 and the bonding layer 112 applied to the through hole 116a is reduced. Therefore, unlike the first comparative example, the wiring line 114a is inhibited from peeling from the terminal 122a.

The opening 115 is provided so as to have a slight length between the wiring line 114b and the through hole 116a of which the distance to the wiring line 114b is the smallest among the through holes 116a. This structure further reduces the stress of the insulating layer 110 and the bonding layer 112 applied to the through hole 116a.

The length of the opening 115 in the Y direction is greater than the length of at least one of the through holes 116a and 116b in the Y direction. That is, as illustrated in FIG. 21B, the positive Y direction end 141a of the opening 115 is located in the positive Y direction relative to the positive Y direction end 140a (the outermost end) of the through hole 116a, i.e., is located further out than the positive Y direction end 140a of the through hole 116a. The negative Y direction end 141b of the opening 115 is located in the negative Y direction relative to the negative Y direction end 140b (the outermost end) of the through hole 116a, i.e., is located further out than the negative Y direction end 140b of the through hole 116a. This structure reduces a stress applied to the through hole 116a. When a plurality of the through holes 116a is provided, the positive Y direction end 141a of the opening 115 is preferably located in the positive Y direction relative to the positive Y direction end of the through hole 116a at the most positive Y position among the through holes 116a, and the negative Y direction end 141b of the opening 115 is preferably located in the negative Y direction relative to the negative Y direction end of the through hole 116a at the most negative Y position among the through holes 116a.

The opening 115 overlaps with the electronic component 120a, and does not overlap with the region outside the electronic component 120a. That is, the positive Y direction end 141a and the negative Y direction end 141b of the opening 115 overlap with the electronic component 120a. This structure secures the bonding between the electronic component 120a and the insulating layer 110 by the bonding layer 112, and thus inhibits the decrease in strength of the insulating layer 110 due to the opening 115, and inhibits breakage of the insulating layer 110 due to the handling of a work during the manufacturing process illustrated in FIG. 24A and FIG. 24B. In addition, to inhibit the peeling of the insulating layer 110, a distance La from the positive Y direction end 141a of the opening 115 to the positive Y direction edge of the electronic component 120a and a distance Lb from the negative Y direction end 141b of the opening 115 to the negative Y direction edge of the electronic component 120a are preferably 0.1 mm or greater.

The electronic component 120a is a transistor, the terminal 122a is the control terminal of the transistor, and the terminal 122b is a terminal (e.g., a source terminal), other than the control terminal, of the transistor. In the transistor, a large current does not flow through the control terminal. Thus, the sum of areas of contact between at least one through hole 116a and the terminal 122a is less than the sum of areas of contact between at least one through hole 116b and the terminal 122b. Thus, a stress is easily applied to the through hole 116a, and the wiring line 114a is more likely to peel from the terminal 122a or the defect due to a crack in the through hole 116a is more likely to occur. Thus, it is preferable to provide the opening 115. The control terminal is a gate terminal or a base terminal, and the terminal other than the control terminal is a source terminal, an emitter terminal, a drain terminal, or a collector terminal.

The thickness of each of the wiring lines 114a and 114b is preferably greater than the total thickness of the insulating layer 110 and the bonding layer 112. This configuration enhances heat release performance from the electronic component 120a. In addition, since the temperature increase of the insulating layer 110 and the bonding layer 112 is inhibited, a current to be supplied to the electronic component 120a can be increased. However, a thermal stress applied from the wiring lines 114a and 114b to the insulating layer 110 and the bonding layer 112 increases. Thus, provision of the opening 115 reduces the stress due to the thick wiring lines 114a and 114b. The thicknesses of the wiring lines 114a and 114b are preferably equal to or greater than 1.5 times, more preferably equal to or greater than 2 times the total thickness of the insulating layer 110 and the bonding layer 112.

The electronic component 120b (a second electronic component) is, for example, a diode, includes the terminal 122d (a third terminal) on the upper surface of the electronic component 120b, and is mounted on the lower surface of the insulating layer 110. The wiring line 114b (at least one of the first wiring line and the second wiring line) connects the terminal 122d and the terminal 122b (a terminal corresponding to the at least one of the first wiring line and the second wiring line of the first terminal and the second terminal). Use of the thick wiring line 114b enables to increase a current capacity between the terminal 122b and the terminal 122d.

### First Variation of the Second Embodiment

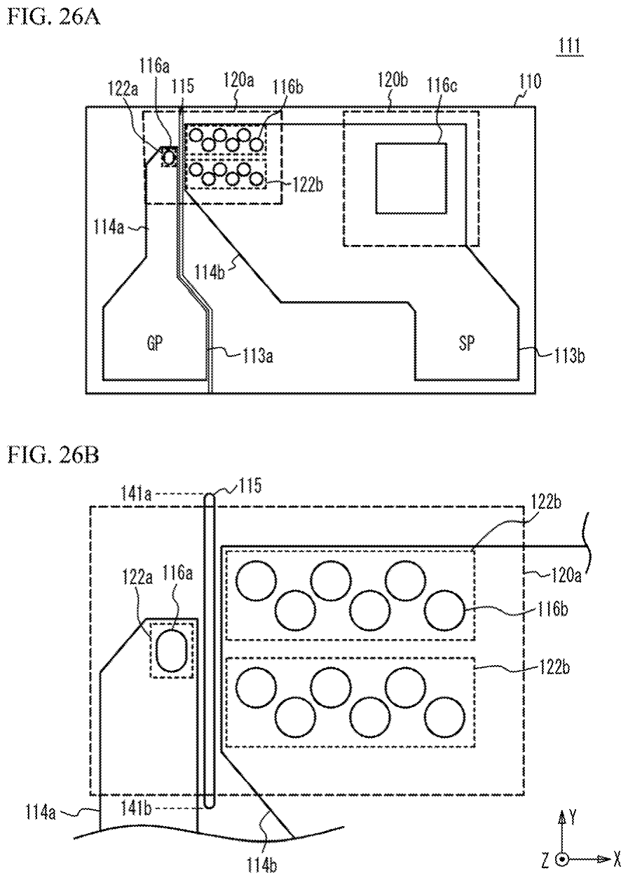

FIG. 26A and FIG. 26B are plan views of modules in accordance with first and second variations of the second embodiment, respectively. FIG. 26B is an enlarged view of a part around the electronic component 120a. As illustrated in FIG. 26A, in the first variation of the second embodiment, the opening 115 passes through the insulating layer 110 between a region where the wiring line 114a is provided and a region where the wiring line 114b is provided, extends from the upper edge to the lower edge of the insulating layer 110, and separates the insulating layer 110 into two regions. Since the opening 115 separates the insulating layer 110, the stress of the insulating layer 110 and the bonding layer 112 applied to the through hole 116a is further reduced. Since the strength of the insulating layer 110 becomes weak, the handling ability during the manufacturing process deteriorates. In this case, the opening 115 may be formed with use of a laser beam after the electronic components 120a and 120b are bonded to the insulating layer 110 on which the wiring lines 114a and 114b are formed.

### Second Variation of the Second Embodiment

As illustrated in FIG. 26B, in the second variation of the second embodiment, the positive Y direction end 141a of the opening 115 is located in the positive Y direction relative to the positive Y direction edge of the electronic component 120a, and the negative Y direction end 141b of the opening 115 is located in the negative Y direction relative to the negative Y direction edge of the electronic component 120a. That is, the opening 115 is provided from the positive Y direction end to the negative Y direction end of the electronic component 120a, and is provided so as to be longer than the length of the electronic component 120a in the Y direction and separate the region between the wiring line 114a and the wiring line 114b in the electronic component 120a. However, the opening 115 does not separate the insulating layer 110. Since the opening 115 is longer than the electronic component 120a, the stress of the insulating layer 110 and the bonding layer 112 applied to the through hole 116a is further reduced. Since the opening 115 does not separate the insulating layer 110, the handling ability during the manufacturing process is enhanced.

In the first and second variations of the second embodiment, a projection region of the opening 115 to the electronic component 120a separates the electronic component 120a into two regions when the opening 115 is projected to the electronic component 120a in the thickness direction of the insulating layer 110. This structure further reduces the stress of the insulating layer 110 and the bonding layer 112 applied to the through hole 116a.

### Third Variation of the Second Embodiment

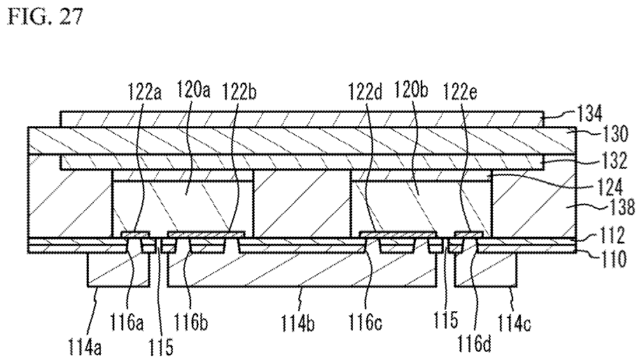

FIG. 27 is a cross-sectional view of a module in accordance with a third variation of the second embodiment. As illustrated in FIG. 27, the electronic components 120a and 120b are mounted on the insulating layer 110 with use of the bonding layer 112. The electronic component 120a is, for example, a horizontal GaN transistor, and the electronic component 120b is a horizontal diode. In the case of the horizontal GaN transistor, the gate terminal, the source terminal, and the drain terminal are all located on the lower surface of the electronic component 120a. In FIG. 27, the terminals 122a and 122b are located on the lower surface of the electronic component 120a. The terminals 122a and 122b are respectively a gate terminal and a source terminal. A drain terminal is located in a position, the cross-section at which is not illustrated, on the lower surface of the electronic component 120a. Terminals 122d and 122e are located on the lower surface of the electronic component 120b that is the horizontal diode. The terminals 122d and 122e are a cathode terminal and an anode terminal, respectively.

Wiring lines 114a through 114c are located on the lower surface of the insulating layer 110. The wiring line 114a is connected to the terminal 122a (a gate terminal) of the electronic component 120a through the through hole 116a. The wiring line 114b is connected to the terminal 122b (a source terminal) of the electronic component 120a through the through hole 116b, and is connected to the terminal 122d (an anode terminal) of the electronic component 120b (a diode) through the through hole 116c. The wiring line 114c is connected to the terminal 122e (a cathode terminal) of the electronic component 120b through a through hole 116d. The opening 115 is provided so as to remove the insulating layer 110 and the bonding layer 112 between the wiring lines 114a and 114b, and the opening 115 is provided so as to remove the insulating layer 110 and the bonding layer 112 between the wiring lines 114b and 114c.

The upper surfaces of the electronic components 120a and 120b (the rear surfaces of the bare chips) are bonded to the lower surface of a metal layer 132 by the bonding layer 124. Metal layers 132 and 134 are located on the lower surface and the upper surface of an insulating substrate 130, respectively. The insulating substrate 130 is, for example, a ceramic substrate, and the metal layers 132 and 134 are, for example, copper layers. The insulating substrate 130 and the metal layers 132 and 134 function as a heatsink that releases heat of the electronic components 120a and 120b. The bonding layer 124 is formed of, for example, a resin adhesive agent or a conductive adhesive agent such as a metal paste. A sealing member 138 may be filled between the insulating layer 110 and the insulating substrate 130. The sealing member 138 is formed of an insulating material such as, but not limited to, a resin, and seals the electronic components 120a and 120b. Other structures are the same as those of the second embodiment, and the description thereof is thus omitted. As described above, even when the module is a module in which the insulating substrate 130, which is a ceramic substrate, is located on the rear surface of the electronic component 120a, which is, for example, a bare chip, the reliability of the contact of the gate terminal in the through hole 116a is enhanced because the opening 115 illustrated in FIG. 21A and FIG. 21B is provided between the through hole 116a (a through hole for the gate terminal) and the terminal 122b (a source terminal).

### Fourth Variation of the Second Embodiment

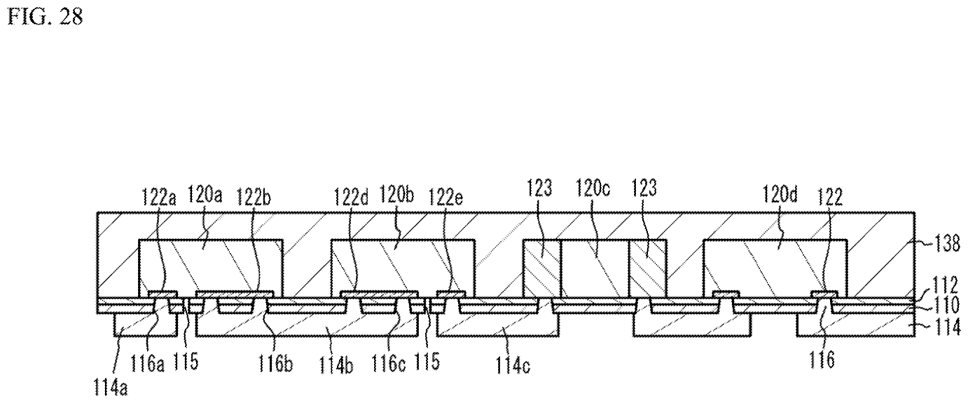

FIG. 28 is a cross-sectional view of a module in accordance with a fourth variation of the second embodiment. As illustrated in FIG. 28, electronic components 120a through 120d are mounted on the insulating layer 110 with use of the bonding layer 112. The electronic component 120a is, for example, a horizontal GaN transistor. The electronic component 120b is, for example, a diode. The electronic component 120c is, for example, a discrete chip resistor, a discrete chip capacitor, and/or a discrete chip inductor. A wiring line 114 is connected to electrodes 122 and 123 of the electronic components 120c and 120d through through holes 116. In the electronic component 120c, the electrode 123 is located on the five surfaces of the electronic component 120c, and the wiring lines 114 and 114c are connected to the electrode 123. The electronic component 120d is, for example, an integrated circuit, and is a driver that drives a power element such as, but not limited to, a transistor. The sealing member 138 is located on the insulating layer 110 so as to cover the electronic components 120a through 120d. The sealing member 138 is made of an insulating material such as a resin, and seals the electronic components 120a through 120d. Other structures are the same as those of the third variation of the second embodiment, and the description thereof is thus omitted.

In the third variation of the second embodiment, the heat release performance of the electronic components 120a and 120b is enhanced by providing the insulating substrate 130 and the metal layers 132 and 134. Thus, the electric power handled by the electronic components 120a and 120b can be made to be 1 KW or greater.

In the fourth variation of the second embodiment, a module including many electronic components 120a through 120d is achieved.

### Fifth Variation of the Second Embodiment

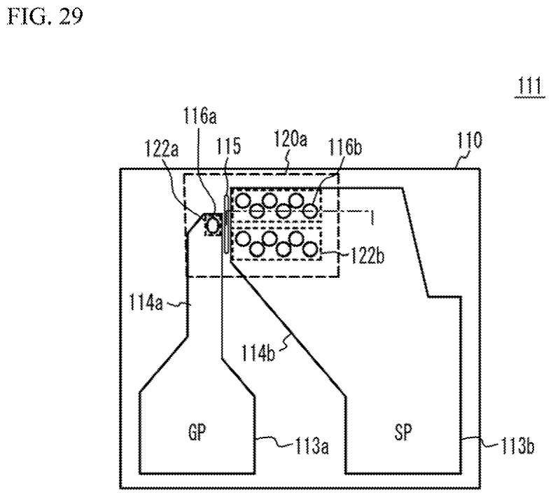

FIG. 29 is a plan view of a sheet module in accordance with a fifth variation of the second embodiment. As illustrated in FIG. 29, the electronic component 120a (for example, a transistor) is mounted on the insulating layer 110, and the electronic component 120b (for example, a diode) is not mounted on the insulating layer 110. Other structures are the same as those of the second embodiment, and the description thereof is thus omitted. As described in the fifth variation of the second embodiment, the number of the electronic components 120a mounted on the insulating layer 110 may be one.

### Sixth Variation of the Second Embodiment

A sixth variation of the second embodiment is an example in which the sheet module 111 is mounted in an insertion-type package (for example, a transistor outline (TO) package) in which a lead is inserted in the hole of a printed circuit board.

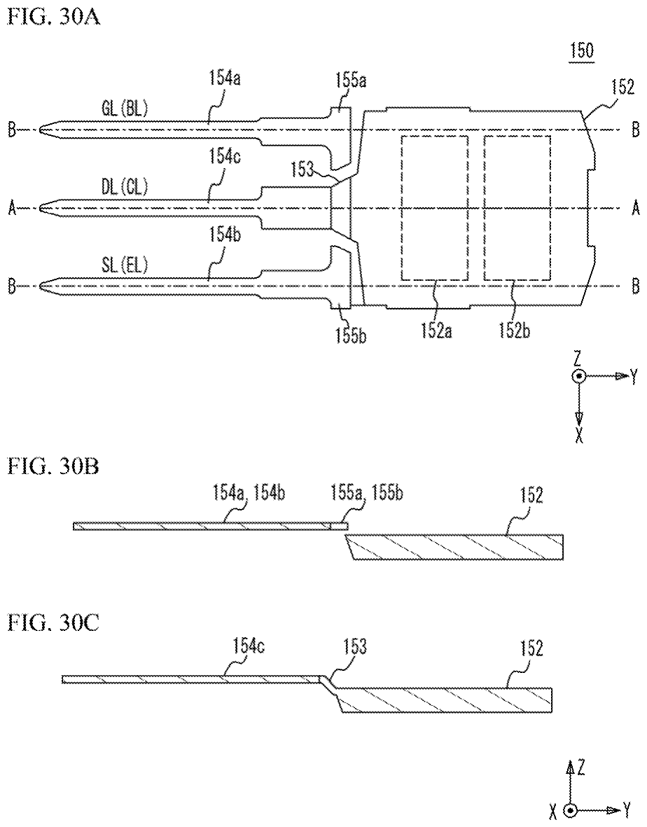

FIG. 30A is a plan view of a lead frame in the sixth variation of the second embodiment, FIG. 30B is a cross-sectional view taken along line A-A in FIG. 30A, and FIG. 30C is a cross-sectional view taken along line B-B in FIG. 30A. As illustrated in FIG. 30A through FIG. 30C, a lead frame 150 is mainly made of copper, and includes a die pad 152 (also referred to as an island) and leads 154a through 154c. The die pad 152 is a metal plate of which the positive Z direction surface and the negative Z direction surface thereof are flat. The lead 154c extending from the die pad 152 in the negative Y direction is a drain lead DL. The lead 154a is connected to the die pad 152 by a connection portion 153. The lead 154a is provided separately from the die pad 152, and is located in the negative X direction relative to the lead 154c. The lead 154b is provided separately from the die pad 152, and is located in the positive X direction relative to the lead 154c.

The positive Y direction ends of the leads 154a and 154b are pads 155a and 155b, respectively. In the positive and negative Z direction surfaces of the pads 155a and 155b, the negative Z direction surfaces to which the pads 113a and 113b are to be connected are flat. When the pads 113a and 113b are connected to the positive Z direction surfaces of the pads 155a and 155b, the positive Z direction surfaces of the pads 155a and 155b are made to be flat. The leads 154a and 154b are a gate lead GL and a source lead SL, respectively. When the transistor is a bipolar transistor or an IGBT, the leads 154a, 154b, and 154c are respectively a base lead BL, an emitter lead EL, and a collector lead CL.

A region 152a of the die pad 152 is a mounting region where the electronic components 120a and 120b such as bare chips are mounted. A region 152b may be a mounting region, but may be a heat release and heatsink region. The die pad 152 is thicker than the leads 154a through 154c. The leads 154a through 154c are located in the positive Z direction relative to the positive Z direction surface of the die pad 152.

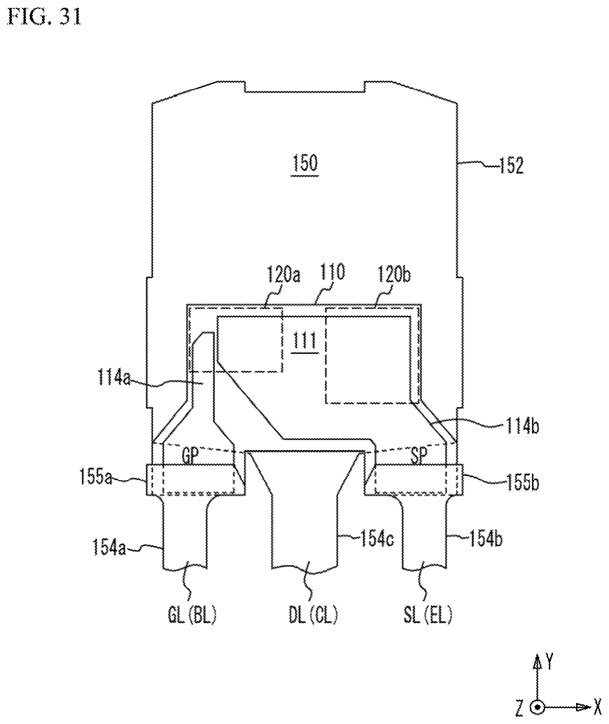

FIG. 31 is a plan view of the module in accordance with the sixth variation of the second embodiment. As illustrated in FIG. 31, the sheet module 111 is mounted on the lead frame 150. The negative Z direction surfaces of the electronic components 120a and 120b are bonded to the positive Z direction surface of the die pad 152 by, for example, a brazing material or a conductive paste. The positive Z direction surfaces of the pads 113a and 113b of the sheet module 111 (see FIG. 29) are respectively bonded to the negative Z direction surfaces of the pads 155a and 155b with use of solder, a conductive paste, or spot welding. Solder or a conductive paste is preferably used for this step. The sheet module 111 and the lead frame 150 other than the leads 154a through 154c may be sealed by a sealing resin.

The terminal 122c (a drain terminal) of the electronic component 120a and the terminal 122e (a cathode terminal) of the electronic component 120b are electrically connected to the lead 154c (a drain lead DL) through the die pad 152 and the connection portion 153 (see FIG. 30A). The terminal 122a (a gate terminal) of the electronic component 120a is electrically connected to the lead 154a (a gate lead GL) through the wiring line 114a, the pad 113a (a gate pad GP), and the pad 155a. The terminal 122b (a source terminal) of the electronic component 120a is electrically connected to the lead 154b (a source lead SL) through the wiring line 114b, the pad 113b (a source pad SP), and the pad 155b.

### Seventh Variation of the Second Embodiment

A seventh variation of the second embodiment is an example in which a sheet module is mounted in a surface-mount package (for example, a small outline package (SOP)) in which a lead is bent, and the lead is fixed to the surface of a printed circuit board.

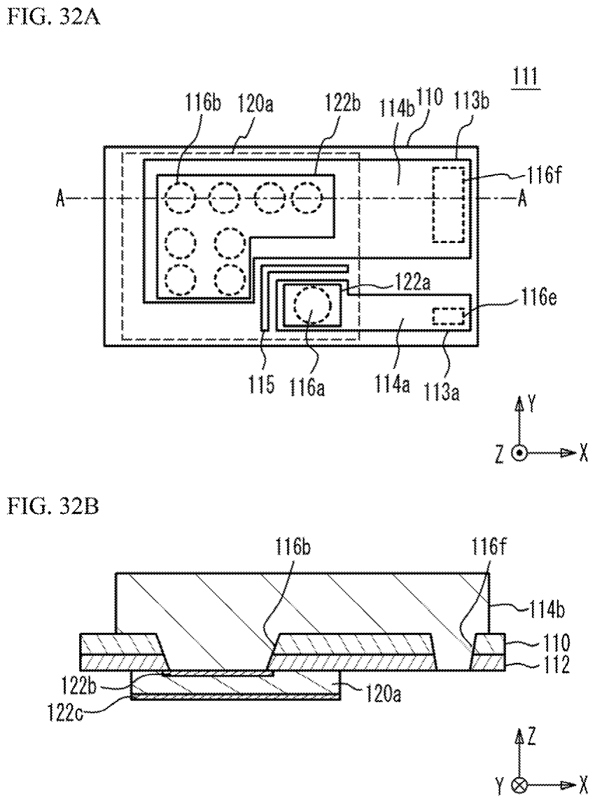

FIG. 32A is a plan view of a sheet module in the seventh variation of the second embodiment, and FIG. 32B is a cross-sectional view taken along line A-A in FIG. 32A. As illustrated in FIG. 32A and FIG. 32B, in the sheet module 111, the electronic component 120a is mounted on the lower surface of the insulating layer 110 by the bonding layer 112. The wiring lines 114a and 114b are located on the upper surface of the insulating layer 110. The wiring lines 114a and 114b are connected to the terminals 122a and 122b through the through holes 116a and 116b, respectively. In FIG. 32B, a plurality of the through holes 116b is illustrated as one through hole.

The L-shaped opening 115 is provided in the insulating layer 110 between the wiring lines 114a and 114b. The wiring lines 114a and 114b extend in the positive X direction. The ends of the wiring lines 114a and 114b are pads 113a and 113b. Through holes 116e and 116f penetrating through the insulating layer 110 and the bonding layer 112 are provided to the pads 113a and 113b, respectively.

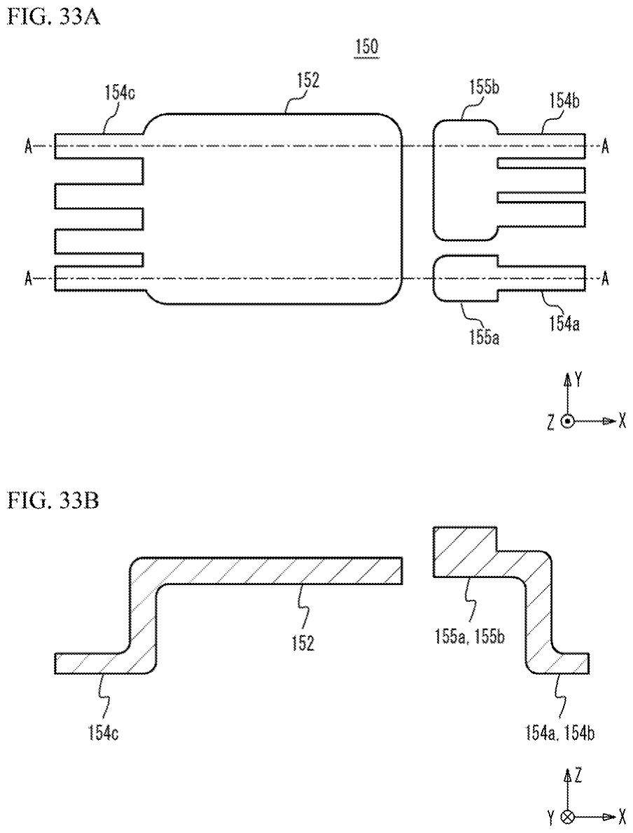

FIG. 33A is a plan view of a lead frame in the seventh variation of the second embodiment, and FIG. 33B is a cross-sectional view taken along line A-A in FIG. 33A. The lead frame 150 includes the die pad 152 and the leads 154a through 154c. The lead 154c is extracted from the die pad 152 in the negative X direction, is bent in the negative Z direction, and is further bent in the negative X direction.

The leads 154a and 154b are separated from the die pad 152. The negative X direction ends of the leads 154a and 154b are the pads 155a and 155b. The pads 155a and 155b are thicker than the die pad 152. The leads 154a and 154b extend from the pads 155a and 155b in the positive X direction, are bent in the negative Z direction, and are further bent in the positive X direction. Since a large current flows through the leads 154b and 154c, the lead 154b is branched in a comb-shape, and the lead 154c is branched in a comb-shape. The negative Z direction surfaces of the ends of the leads 154a through 154c are mounted on the surface of a printed circuit board.

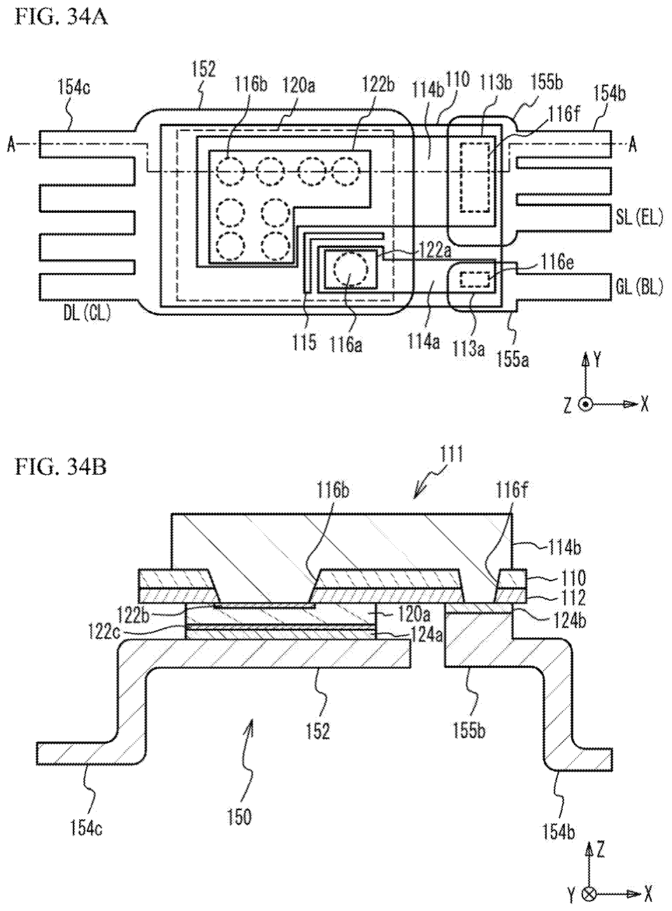

FIG. 34A is a plan view of the module in the seventh variation of the second embodiment, and FIG. 34B is a cross-sectional view taken along line A-A in FIG. 34A. As illustrated in FIG. 34A and FIG. 34B, the sheet module 111 is mounted on the lead frame 150. The terminal 122c of the electronic component 120a is bonded to the die pad 152 through a bonding layer 124a. The wiring line 114a in the through hole 116e is bonded to the pad 155a through a bonding layer 124b. The wiring line 114b in the through hole 116f is bonded to the pad 155b through the bonding layer 124b. The bonding layers 124a and 124b are formed of, for example, solder or a conductive paste.

The terminal 122a (a gate terminal) of the electronic component 120a is electrically connected to the lead 154a (a gate lead GL) through the wiring line 114a, the pad 113a, the bonding layer 124b, and the pad 155a. The terminal 122b (a source terminal) of the electronic component 120a is electrically connected to the lead 154b (a source lead SL) through the wiring line 114b, the pad 113b, the bonding layer 124b, and the pad 155b. The terminal 122c (a drain terminal) of the electronic component 120a is electrically connected to the lead 154c (a drain lead DL) through the bonding layer 124a and the die pad 152. The leads 154a, 154b, and 154c may be a base lead BL, an emitter lead EL, and a collector lead CL, respectively.

As in the third variation of the second embodiment, the sheet module 111 may be mounted on a conductive pattern located on a substrate including at least one insulating layer made of a resin or ceramic. As in the fifth and sixth variations of the second embodiment, the sheet module 111 may be mounted on the die pad 152 of a lead frame formed by die-cutting a metal plate or etching a metal plate. The sheet module 111 may be mounted on a metal substrate (mainly made of, for example, copper or aluminum) insulated by a resin material. The sheet module 111 may be mounted on a conductive metal plate (mainly made of, for example, copper, aluminum, iron, or stainless steel). The planar shapes of the metal substrate and the metal plate are rectangular or elliptic.

The second embodiment and the variations thereof have described a power module in which a power semiconductor element is mounted, but the module may be a module in which an electronic component other than the power semiconductor element is mounted.

Although the embodiments of the present invention have been described in detail, it is to be understood that the various change, substitutions, and alterations could be made hereto without departing from the spirit and scope of the invention.

What is claimed is:

1. A module comprising:
a resin insulating layer;
a first electronic component mounted on a lower surface of the resin insulating layer, the first electronic component including a first terminal and a second terminal on an upper surface of the first electronic component;
a resin bonding layer bonding the lower surface of the resin insulating layer to the upper surface of the first electronic component;
a first wiring line located on an inner surface of at least one first through hole and an upper surface of the resin insulating layer, the first wiring line connecting to the first terminal, the at least one first through hole penetrating through the resin insulating layer and the resin bonding layer; and
a second wiring line located on an inner surface of at least one second through hole and an upper surface of the resin insulating layer, the second wiring line connecting to the second terminal, the at least one second through hole penetrating through the resin insulating layer and the resin bonding layer, wherein
an opening penetrating through the resin insulating layer and the resin bonding layer is provided between the first terminal and the second terminal and between the first wiring line and the second wiring line, and no other metal layers are provided.

2. The module according to claim 1, wherein
a sum of areas of contact between at least one first through hole and the first terminal is less than a sum of areas of contact between the at least one second through hole and the second terminal.

3. The module according to claim 2, wherein
the opening is located between the second wiring line and a first through hole of which a distance to the second wiring line is smallest among the at least one first through hole.

4. The module according to claim 3, wherein
an end of the opening is located further out than an outermost end of the at least one first through hole.

5. The module according to claim 2, wherein
the first electronic component is a transistor,
the first terminal is a control terminal of the transistor, and
the second terminal is a terminal of the transistor other than the control terminal.

6. The module according to claim 1, wherein
the opening overlaps with the first electronic component in a thickness direction of the resin insulating layer, and does not overlap with a region outside the first electronic component in the thickness direction of the resin insulating layer.

7. The module according to claim 1, wherein
a projection region of the opening to the first electronic component separates the first electronic component into two regions when the opening is projected to the first electronic component in a thickness direction of the resin insulating layer.

8. The module according to claim 1, wherein
a thickness of each of the first wiring line and the second wiring line is greater than a total thickness of the resin insulating layer and the resin bonding layer.

9. The module according to claim 1, further comprising
a second electronic component mounted on the lower surface of the resin insulating layer, the second electronic component including a third terminal on an upper surface of the second electronic component, wherein
at least one of the first wiring line and the second wiring line connects the third terminal and a terminal corresponding to the at least one of the first wiring line and the second wiring line of the first terminal and the second terminal.

10. A module comprising:
a sheet module including an insulating layer, an electronic component, a first wiring line, and a second wiring line, the electronic component being mounted on a lower surface of the insulating layer, the first wiring line being electrically connected to the electronic component through a first through hole, extending on an upper surface of the insulating layer, and including a first pad in an end of the first wiring line, the first through hole penetrating through the insulating layer, the second wiring line being electrically connected to the electronic component through a second through hole, extending on the upper surface of the insulating layer, and including a second pad in an end of the second wiring line, the second through hole penetrating through the insulating layer;
a die pad to which a lower surface of the electronic component is bonded,
a first lead including a first frame pad to which the first pad is bonded, the first lead extending from the first frame pad;
a second lead including a second frame pad to which the second pad is bonded, the second lead extending from the second frame pad in a direction substantially parallel to an extension direction of the first lead; and
a third lead located between the first lead and the second lead and integrally formed with the die pad, the third lead extending in a direction substantially parallel to the extension direction of the first lead and an extension direction of the second lead.

11. The module according to claim 10, wherein
a cutout is provided in the insulating layer between the first frame pad and the third lead and/or the insulating layer between the second frame pad and the third lead.

12. The module according to claim 10, wherein
an upper surface of the first pad is bonded to a lower surface of the first frame pad, and
an upper surface of the second pad is bonded to a lower surface of the second frame pad.

13. The module according to claim 10, wherein
a lower surface of the first pad is bonded to an upper surface of the first frame pad, and
a lower surface of the second pad is bonded to an upper surface of the second frame pad.

14. The module according to claim 10, wherein
a lower surface of the first pad is bonded to an upper surface of the first frame pad through a first shim, and
a lower surface of the second pad is bonded to an upper surface of the second frame pad through a second shim.

15. The module according to claim 10, wherein
the sheet module includes a plurality of the electronic components.

16. The module according to claim 10, wherein
the electronic component is a power semiconductor element, and
the insulating layer is formed of a polyimide sheet.

17. The module according to claim 10, wherein
the electronic component includes a first electronic component and a second electronic component, and
a slit penetrating through the insulating layer is provided in the insulating layer between the first electronic component and the second electronic component.

18. A module comprising:
an insulating layer having a flexibility;
an electronic component mounted on a lower surface of the insulating layer;
a wiring line electrically connected to the electronic component through a through hole penetrating through the insulating layer, the wiring line extending on an upper surface of the insulating layer, and including a pad in an end of the wiring line; and
a metal layer located on the insulating layer so as to surround an opening provided to the insulating layer adjacent to the pad.
